(19) United States
(12) Patent Application Publication
(10) Pub. No.: US 2025/0112101 A1
(43) Pub. Date: Apr. 3, 2025

(54) CURABLE RESIN FILM, COMPOSITE SHEET, SEMICONDUCTOR CHIP, AND SEMICONDUCTOR CHIP MANUFACTURING METHOD

(71) Applicant: LINTEC CORPORATION, Tokyo (JP)

(72) Inventor: Reina KAINUMA, Saitama-shi, Saitama (JP)

(73) Assignee: LINTEC CORPORATION, Tokyo (JP)

(21) Appl. No.: 18/832,340

(22) PCT Filed: Jan. 19, 2023
(86) PCT No.: PCT/JP2023/001566

§ 371 Date: Jul. 23, 2024

(30) Foreign Application Priority Data
Jan. 28, 2022 (JP) 2022-012254
Jan. 28, 2022 (JP) 2022-012257

(51) Int. Cl. H01L 23/31; H01L 21/56; H01L 21/78; H01L 23/29; H01L 23/552

(52) U.S. Cl. CPC H01L 23/3185; H01L 21/561; H01L 21/78; H01L 23/293; H01L 23/552

(57) ABSTRACT

Provided is a curable resin film for use in forming a cured resin film as a protective film on a bump-formed surface of a semiconductor chip having the bump-formed surface provided with a bump, the curable resin film satisfying requirement (1) below: requirement (1): a near-infrared transmittance at 940 nm is less than 13% after thermal curing treatment at 130° C. and 0.5 MPa for 240 minutes.

### TECHNICAL FIELD

The present invention relates to a curable resin film, a composite sheet, a semiconductor chip, and a method for manufacturing a semiconductor chip. More specifically, the present invention relates to a curable resin film; a composite sheet including the curable resin film; a semiconductor chip produced by using these, wherein a cured resin film is provided as a protective film; and a method for manufacturing the semiconductor chip.

### BACKGROUND ART

In recent years, semiconductor devices have been manufactured using a mounting method called the face-down method. In the face-down method, a semiconductor chip provided with a bump on a circuit surface and a substrate for mounting the semiconductor chip are laminated to allow the circuit surface of the semiconductor chip to face the substrate, whereby the semiconductor chip is mounted on the substrate.

The semiconductor chip is typically obtained by singulating a semiconductor wafer provided with bumps on the circuit surface into individual pieces.

A semiconductor wafer provided with bumps may be provided with a protective film to protect joint portions (hereinafter also referred to as a “bump neck”) between the bumps and the semiconductor wafer.

For example, in Patent Literature 1, a laminate in which a supporting substrate, a pressure sensitive adhesive layer, and a curable resin layer are laminated in this order is attached by pressing to a bump-formed surface of a semiconductor wafer provided with bumps using the curable resin layer as the bonding surface, then the curable resin layer is cured by heating, to thereby form a protective film.

In the method described in Patent Literature 1, the protective film is formed on the wafer with bumps, and then the wafer with bumps is diced together with the protective film to produce singulated semiconductor chips.

### CITATION LIST

### Patent Literature

Patent Literature 1: JP 2015-092594 A

### SUMMARY OF INVENTION

### Technical Problem

In recent years, a technique for transmitting and receiving data by infrared rays (hereinafter, referred to as “infrared communication”) has been used in various devices. Thus, in a semiconductor device including a semiconductor chip, it is required to prevent malfunction caused by near-infrared rays (750 nm to 1500 nm band) used in the infrared communication.

The present inventor has come up with the idea that when a function of preventing malfunction caused by near infrared rays is imparted to a protective film of a semiconductor chip on which the protective film is formed, the function of preventing malfunction caused by near-infrared rays can be easily imparted to the semiconductor chip on which the protective film is formed. However, prevention of malfunction caused by near-infrared rays by the protective film has not been sufficiently studied.

Accordingly, an object of the present invention is to provide a curable resin film which is used for forming a cured resin film as a protective film on a bump-formed surface of a semiconductor chip having the bump-formed surface provided with bumps, and which can suppress malfunction of the semiconductor chip caused by near-infrared rays, a composite sheet including the curable resin film, a semiconductor chip, and a method for manufacturing the semiconductor chip.

### Solution to Problem

According to the present invention, the following [1] to are provided.
[1] A curable resin film for use in forming a cured resin film as a protective film on a bump-formed surface of a semiconductor chip having the bump-formed surface provided with a bump, the curable resin film satisfying requirement (1) below:
requirement (1): a near-infrared transmittance at 940 nm is less than 13% after thermal curing treatment at 130° C. and 0.5 MPa for 240 minutes.
[2] The curable resin film according to [1] above, which contains a black pigment.
[3] The curable resin film according to [2] above, wherein a content of the black pigment is more than 0.5 mass % based on an entire amount of the curable resin film.
[4] The curable resin film according to any one of [1] to [3] above, which has a thickness of 1 μm or more.
[5] The curable resin film according to any one of [1] to [4] above, which is used for forming the cured resin film as the protective film on both the bump-formed surface and a side surface of the semiconductor chip.
[6] A composite sheet having a laminated structure in which the curable resin film described in any one of [1] to [5] above and a release sheet are laminated.
[7] The composite sheet according to [6] above, wherein the release sheet includes a substrate and a release layer, and the release layer faces the curable resin film.
[8] The composite sheet according to [7] above, wherein the release sheet further includes an intermediate layer between the substrate and the release layer.
[9] The composite sheet according to [7] or [8] above, wherein the release layer is a layer formed from a composition containing an ethylene-vinyl acetate copolymer.
[10] A method for manufacturing a semiconductor chip, the method including steps (V1) to (V4) below in this order:
step (V1): preparing a semiconductor wafer having a bump-formed surface provided with a bump;
step (V2): attaching the curable resin film described in any one of [1] to [4] above by pressing to the bump-formed surface of the semiconductor wafer to cover the bump-formed surface of the semiconductor wafer with the curable resin film;
step (V3): curing the curable resin film to yield a semiconductor wafer having a cured resin film; and
step (V4): singulating the semiconductor wafer having the cured resin film into individual pieces to produce a semiconductor chip in which the bump-formed surface is covered with the cured resin film.
[11] A method for manufacturing a semiconductor chip, the method including steps (S1), (S2), (S3), and (S4) below in this order:
step (S1): preparing a semiconductor chip-producing wafer in which grooves as predetermined singulation lines are formed in a bump-formed surface of a semiconductor wafer having the bump-formed surface provided with bumps, the grooves not reaching a back surface of the semiconductor wafer;
step (S2): attaching the curable resin film described in [5] above by pressing to the bump-formed surface of the semiconductor chip-producing wafer to cover the bump-formed surface of the semiconductor chip-producing wafer with the curable resin film and to embed the curable resin film into the grooves formed in the semiconductor chip-producing wafer;
step (S3): curing the curable resin film to yield a semiconductor chip-producing wafer having a cured resin film; and
step (S4): singulating the semiconductor chip-producing wafer having the cured resin film along the predetermined singulation lines into individual pieces to produce a semiconductor chip in which at least the bump-formed surface and a side surface are covered with the cured resin film, and
the method further including step (S-BG) below after step (S2) and before step (S3), after step (S3) and before step (S4), or in step (S4):
step (S-BG): grinding the back surface of the semiconductor chip-producing wafer.
[12] The method for manufacturing a semiconductor chip according to above, which further includes step (TA) below:
step (TA): forming a back surface protective film on the back surface of the semiconductor wafer.
[13] The method for manufacturing a semiconductor chip according to above, which further includes step (TB) below:
step (TB): forming a back surface protective film on the back surface of the semiconductor chip-producing wafer.
[14] A semiconductor chip having a cured resin film formed by curing the curable resin film described in any one of [1] to [4] above on a bump-formed surface of the semiconductor chip having the bump-formed surface provided with a bump, the semiconductor chip being provided with a near-infrared shielding function.
[15] A semiconductor chip having a cured resin film formed by curing the curable resin film described in [5] above on both a bump-formed surface and a side surface of the semiconductor chip having the bump-formed surface provided with a bump, the semiconductor chip being provided with a near-infrared shielding function.
[16] The semiconductor chip according to or above, which further has a back surface protective film on a back surface of the semiconductor chip.

### Advantageous Effects of Invention

According to the present invention, it is possible to provide a curable resin film which is used for forming a cured resin film as a protective film on a bump-formed surface of a semiconductor chip having the bump-formed surface provided with bumps, and which is capable of suppressing malfunction of the semiconductor chip caused by infrared rays; a composite sheet including the curable resin film; a semiconductor chip;

and a method for manufacturing the semiconductor chip.

### BRIEF DESCRIPTION OF DRAWINGS

FIG. 1 is a schematic cross-sectional view illustrating a structure of a composite sheet according to an embodiment.

FIG. 2 is a schematic cross-sectional view illustrating a structure of a composite sheet according to another embodiment.

FIG. 3 is a schematic cross-sectional view illustrating an example of a semiconductor chip-producing wafer to be prepared in step (S1).

FIG. 4 is a diagram illustrating an outline of step (S2).

FIG. 5 is a diagram illustrating an outline of step (S3).

FIG. 6 is a diagram illustrating an outline of step (S4).

FIG. 7 is a diagram illustrating an outline of step (S-BG).

FIG. 8 is a diagram illustrating an outline of step (V4).

FIG. 9 is an image obtained by photographing a semiconductor chip-producing wafer having a cured resin film from the cured resin film side in evaluation of “4-2. Kerf Recognition Property” and illustrating an example of a case where unevenness of a kerf can be clearly recognized.

FIG. 10 is an image obtained by photographing a semiconductor chip-producing wafer having a cured resin film from the cured resin film side in the evaluation of “4-2. Kerf Recognition Property” and illustrating an example of a case where unevenness of a kerf cannot be clearly recognized.

### DESCRIPTION OF EMBODIMENTS

In the present specification, “active components” refer to components contained in a target composition except for a diluent solvent such as water or an organic solvent.

In addition, in the present specification, “(meth)acrylic acid” refers to both “acrylic acid” and “methacrylic acid”, and the same shall apply to other similar terms.

Furthermore, in the present specification, “weight average molecular weight” or “number average molecular weight” is a value in terms of polystyrene as measured by gel permeation chromatography (GPC).

Moreover, in the present specification, the lower and upper limits of a preferred numerical range (e.g., a range of content) described in series can each be independently combined. For example, from the description “preferably from 10 to 90, more preferably from 30 to 60”, the “preferred lower limit (10)” and the “preferred upper limit (60)” can be combined as “from 10 to 60”.

In the present specification, “the content of each component in the total amount of the active components of the curable resin composition” is synonymous with “the content of each component of the curable resin film formed from the curable resin composition”.

### Aspect of Curable Resin Film of Present Embodiment

The curable resin film of the present embodiment is a curable resin film for use in forming a cured resin film as a protective film on a bump-formed surface of a semiconductor chip having the bump-formed surface provided with a bump, the curable resin film satisfying requirement (1) below:
requirement (1): a near-infrared transmittance at 940 nm is less than 13% after thermal curing treatment at 130° C. and 0.5 MPa for 240 minutes.

When the near-infrared transmittance at 940 nm defined by requirement (1) above is 13% or more, it is difficult to suppress malfunction of the semiconductor chip caused by near-infrared rays.

Here, the near-infrared transmittance at 940 nm defined by requirement (1) above is preferably 10% or less, more preferably 7.0% or less, even more preferably 5.0% or less, and still even more preferably 3.0% or less, from the viewpoint of more easily suppressing malfunction of the semiconductor chip caused by near-infrared rays.

In addition, a near-infrared transmittance at 800 nm is preferably 30% or less, more preferably 26% or less, and even more preferably 25% or less, from the viewpoint of more easily suppressing malfunction of the semiconductor chip caused by near-infrared rays.

In the present specification, the infrared transmittance means a near-infrared transmittance measured by a method described in Examples below.

The method for preparing a curable resin film satisfying requirement (1) above is not particularly limited, and examples thereof include a method in which near-infrared shielding particles are incorporated in the curable resin film.

The near-infrared shielding particles used may be of any known type, and may be of a near-infrared absorption type or a near-infrared reflection type. One type of the near-infrared shielding particles may be used alone, or two or more types thereof may be used in combination.

Examples of the near-infrared shielding particles include particles of noble metals such as gold and silver; tin-doped indium oxide particles (ITO particles); antimony-doped tin oxide particles; cesium-doped tungsten oxide particles; lanthanum hexaboride; dyes; pigments; alumina; and silicon carbide.

Among these, pigments are preferred from the viewpoint of easy availability. Among pigments, a black pigment is preferred from the viewpoint of excellent near-infrared shielding performance. That is, the curable resin film of the present embodiment preferably contains a pigment, and more preferably contains a black pigment.

Examples of the black pigment include carbon black, copper oxide, triiron tetraoxide, manganese dioxide, aniline black, and activated carbon.

Among these, carbon black is preferred from the viewpoint of easy availability.

The content of the black pigment in the curable resin film is preferably more than 0.5 mass %, more preferably 0.7 mass % or more, even more preferably 1.0 mass % or more, and still even more preferably 1.5 mass % or more, based on the entire amount of the curable resin film, from the viewpoint of easily satisfying requirement (1) above.

From the viewpoint of ensuring a film-forming property of the curable resin film, the content of the black pigment is preferably less than 35 mass %, more preferably 30 mass % or less, and even more preferably 25 mass % or less, based on the entire amount of the curable resin film.

In addition, the particle size of the black pigment is preferably from 1 nm to 1 μm, more preferably from 10 nm to 500 nm, and even more preferably from 10 nm to 100 nm, from the viewpoint of easily achieving good uniform dispersibility of the black pigment in the curable resin film.

In the present specification, the particle size of the black pigment means an arithmetic average particle size obtained by averaging the particle sizes of a plurality of randomly selected primary particles of the black pigment as observed and measured with an electron microscope.

Another example of the method for preparing a curable resin film satisfying requirement (1) above is a method in which the thickness of the curable resin film is increased.

When the thickness of the curable resin film is increased, the infrared shielding performance of the cured resin film after thermal curing is slightly improved, and requirement (1) above can be more easily satisfied.

Specifically, the thickness of the curable resin film is preferably 1 μm or more, more preferably 3 μm or more, and even more preferably 5 μm or more.

The thickness of the curable resin film is preferably 250 μm or less, more preferably 200 μm or less, and even more preferably 150 μm or less, from the viewpoint of suppressing contamination due to bleeding at the time of attachment.

The curable resin film may be composed of only one layer (single layer) or may be composed of a plurality of layers; i.e., two or more layers. In a case where the curable resin film is composed of a plurality of layers, these layers may be identical to or different from one another, and the combination of these layers is not particularly limited.

For example, the curable resin film may be composed of a plurality of layers, and near-infrared shielding particles such as a black pigment may be contained only in at least one layer (for example, the outermost surface).

The “thickness of curable resin film” means the thickness of a curable resin film as a whole, and for example, the thickness of a curable resin film composed of a plurality of layers means the total thickness of all the layers constituting the curable resin film.

### Preferred Application of Curable Resin Film of Present Embodiment

The curable resin film of the present embodiment is used for forming a cured resin film as a protective film on a bump-formed surface of a semiconductor chip having the bump-formed surface provided with a bump.

Here, the curable resin film of the present embodiment is preferably used for forming a cured resin film as a protective film on both a bump-formed surface and a side surface of a semiconductor chip having the bump-formed surface provided with a bump, from the viewpoint of improving the strength of the semiconductor chip and more easily suppressing malfunctions of the semiconductor chip caused by near-infrared rays.

From such a viewpoint, it is preferable that the curable resin film of the present embodiment further satisfies requirement (2) described below, in addition to requirement (1) above.

### Requirement (2)

Requirement (2) is defined as follows.

Requirement (2): when a strain is generated on a test piece of the curable resin film having a diameter of 25 mm and a thickness of 1 mm under conditions of a temperature of 90° C. and a frequency of 1 Hz to measure a storage modulus of the test piece, a storage modulus of the test piece at a strain of 1% is defined as Gel, and a storage modulus of the test piece at a strain of 300% is defined as Gc300, an X value calculated from formula (i) below is 10 or more and less than 10000:

$$X = Gc 1 / Gc 300 \qquad ( i )$$

From the viewpoint of forming the protective film having excellent coatability, the upper limit of the X value specified in requirement (2) above is preferably 5000 or less, more preferably 2000 or less, even more preferably 1000 or less, still more preferably 500 or less, yet more preferably 300 or less, still even more preferably 100 or less, and yet even more preferably 80 or less.

In addition, from the viewpoint of achieving a better embedding property into the grooves of the semiconductor chip-producing wafer, the lower limit of the X value specified in requirement (2) above is preferably 20 or more, and more preferably 30 or more.

In the curable resin film of the present embodiment, Gel is not particularly limited as long as the X value specified in requirement (2) is 10 or more and less than 10000.

However, from the viewpoint of more easily forming the protective film having excellent coatability, Gc1 is preferably from 1×10² to 1×10⁶ Pa, more preferably from 2×10³ to 7×10⁵ Pa, and even more preferably from 3×10³ to 5×10⁵ Pa.

In the curable resin film of the present embodiment, Gc300 is not particularly limited as long as the X value is 10 or more and less than 10000.

However, Gc300 is preferably 10 to 15000 Pa, more preferably 30 to 10000 Pa, and even more preferably 60 to 5000 Pa, from the viewpoint of achieving a better embedding property of the curable resin film into the bump neck and a better embedding property of the film into the grooves of the semiconductor chip-producing wafer after penetration of the bump through the curable resin film.

The curable resin film of the present embodiment is cured by heating or energy ray irradiation to form a cured resin film. The curable resin film of the present embodiment may be a thermosetting resin film which is cured by heating, or may be an energy ray-curable resin film which is cured by energy ray irradiation. However, a thermosetting resin film is preferred from the viewpoint of handleability.

The configuration of the thermosetting resin film of the present embodiment will next be described in detail based on conditions for satisfying the above-mentioned requirement (1) and requirement (2).

### Thermosetting Resin Film

The thermosetting resin film of the present embodiment is cured by heating to form a cured resin film.

The thermosetting resin film of the present embodiment contains a polymer component (A) and a thermosetting component (B). The thermosetting resin film of the present embodiment is formed from, for example, a thermosetting resin composition containing the polymer component (A) and the thermosetting component (B).

The polymer component (A) is a component that can be regarded as being formed by a polymerization reaction of a polymerizable compound. The thermosetting component (B) is a component that can undergo a curing (polymerization) reaction with heat as a trigger for the reaction. The curing (polymerization) reaction also includes a polycondensation reaction.

### Polymer Component (A)

The thermosetting resin film and the thermosetting resin composition contain the polymer component (A).

The polymer component (A) is a polymer compound for imparting film formability or flexibility to the thermosetting resin film. One polymer component (A) may be used alone, or two or more polymer components (A) may be used in combination. When two or more polymer components (A) are used in combination, the combination and proportions of the components can be optionally selected.

Examples of the polymer component (A) include acrylic resins, polyarylate resins, poly(vinyl acetal), polyester, urethane-based resins (resins having a urethane bond), acrylic urethane resins, silicone-based resins (resins having a siloxane bond), rubber-based resins (resins having a rubber structure), phenoxy resins, and thermosetting polyimide.

Among these, an acrylic resin, a polyarylate resin, and poly(vinyl acetal) are preferred.

Examples of the acrylic resin include known acrylic polymers.

The weight average molecular weight (Mw) of the acrylic resin is preferably from 10000 to 2000000, more preferably from 300000 to 1500000, and even more preferably from 500000 to 1000000.

When the weight average molecular weight of the acrylic resin is the lower limit described above or more, the shape stability (stability over time during storage) of the thermosetting resin film is readily improved. Meanwhile, when the weight average molecular weight of the acrylic resin is the upper limit described above or less, the thermosetting resin film easily conforms to an uneven surface of an adherend, and for example, generation of voids is readily suppressed between the adherend and the thermosetting resin film. Thus, this improves the coatability on the bump-formed surface of the semiconductor wafer, and easily improves the embedding property into the grooves. Accordingly, requirement (2) above can be easily satisfied.

The glass transition temperature (Tg) of the acrylic resin is preferably from −60 to 70° C., more preferably from −40 to 50° C., and even more preferably from −30° C. to 30° C. from the viewpoint of the attachability and handling property of the thermosetting resin film.

Examples of the acrylic resin include polymers of one type or two or more types of (meth)acrylic esters; and copolymers of two or more types of monomers selected from (meth)acrylic acid, itaconic acid, vinyl acetate, acrylonitrile, styrene, and N-methylolacrylamide.

Examples of the (meth)acrylic ester constituting the acrylic resin include:
alkyl (meth)acrylates in which the alkyl group constituting the alkyl ester has a chain structure having from 1 to 18 carbons, such as methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, tert-butyl (meth)acrylate, pentyl (meth)acrylate, hexyl (meth)acrylate, heptyl (meth)acrylate, 2-ethylhexyl (meth)acrylate, isooctyl (meth)acrylate, n-octyl (meth)acrylate, n-nonyl (meth)acrylate, isononyl (meth)acrylate, decyl (meth)acrylate, undecyl (meth)acrylate, dodecyl (meth)acrylate (lauryl (meth)acrylate), tridecyl (meth)acrylate, tetradecyl (meth)acrylate (myristyl (meth)acrylate), pentadecyl (meth)acrylate, hexadecyl (meth)acrylate (palmityl (meth)acrylate), heptadecyl (meth)acrylate, and octadecyl (meth)acrylate (stearyl (meth)acrylate);
cycloalkyl (meth)acrylates, such as isobornyl (meth)acrylate and dicyclopentanyl (meth)acrylate;
aralkyl (meth)acrylates, such as benzyl (meth)acrylate;
cycloalkenyl (meth)acrylates, such as dicyclopentenyl (meth)acrylate;
cycloalkenyloxyalkyl (meth)acrylates, such as dicyclopentenyloxyethyl (meth)acrylate;
(meth)acrylic imide;
glycidyl group-containing (meth)acrylates, such as glycidyl (meth)acrylate;
hydroxyl group-containing (meth)acrylates, such as hydroxymethyl (meth)acrylate, 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, and 4-hydroxybutyl (meth)acrylate; and
substituted amino group-containing (meth)acrylates, such as N-methylaminoethyl (meth)acrylate.

In the present specification, the “substituted amino group” means a group in which one or two hydrogen atoms of an amino group are replaced by a group(s) other than a hydrogen atom(s).

Among these, from the viewpoint of film formability of the thermosetting resin film and attachability of the thermosetting resin film to the protective film-formed surface of the semiconductor chip, the (meth)acrylic ester is preferably a copolymer formed by combining an alkyl (meth)acrylate in which the alkyl group constituting the alkyl ester has a chain structure having from 1 to 18 carbon atoms, a glycidyl group-containing (meth)acrylate, and a hydroxyl group-containing (meth)acrylate, more preferably a copolymer formed by combining an alkyl (meth)acrylate in which the alkyl group constituting the alkyl ester has a chain structure having from 1 to 4 carbon atoms, a glycidyl group-containing (meth)acrylate, and a hydroxyl group-containing (meth)acrylate, and even more preferably a copolymer formed by combining butyl acrylate, methyl acrylate, glycidyl acrylate, and 2-hydroxyethyl acrylate.

The acrylic resin may be a resin formed by copolymerization of one or more types of monomers selected from, for example, (meth)acrylic acid, itaconic acid, vinyl acetate, acrylonitrile, styrene, and N-methylolacrylamide in addition to (meth)acrylic esters.

One type of monomer constituting the acrylic resin may be used alone, or two or more types of monomers constituting the acrylic resin may be used in combination. When two or more types of monomers constitute the acrylic resin, their combination and proportions can be optionally selected.

The polyarylate resin in the polymer component (A) may be a known resin, and examples thereof include a resin having a basic structure formed by polycondensation of dihydric phenol and a dibasic acid such as phthalic acid or carboxylic acid. Among them, a polycondensate of bisphenol A and phthalic acid, a poly(4,4′-isopropylidenediphenylene terephthalate)/isophthalate) copolymer, and derivatives thereof are preferred.

Examples of the poly(vinyl acetal) in the polymer component (A) include commonly known ones.

Among them, the poly(vinyl acetal) is preferably, for example, poly(vinyl formal) or poly(vinyl butyral), and is more preferably poly(vinyl butyral).

Examples of the poly(vinyl butyral) include those having constitutional units represented by Formulae (i-1), (i-2), and (i-3) below.

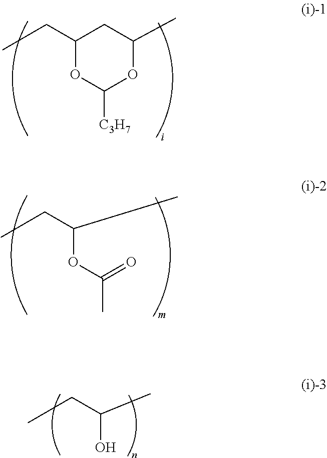

(In the formulae, l, m, and n are each independently an integer of 1 or more.)

The weight average molecular weight (Mw) of the poly(vinyl acetal) is preferably from 5000 to 200000, and more preferably from 8000 to 100000. When the weight average molecular weight of the poly(vinyl acetal) is the lower limit described above or more, the shape stability (stability over time during storage) of the thermosetting resin film is readily improved. Meanwhile, when the weight average molecular weight of the poly(vinyl acetal) is the upper limit described above or less, the thermosetting resin film easily conforms to an uneven surface of an adherend, and for example, generation of voids is easily suppressed between the adherend and the thermosetting resin film. Thus, this improves the coatability on the bump-formed surface of the semiconductor wafer, and easily improves the embedding property into the grooves. Accordingly, requirement (2) above can be easily satisfied.

The glass transition temperature (Tg) of the poly(vinyl acetal) is preferably from 40 to 80° C. and more preferably from 50 to 70° C., from the viewpoint of the film formability of the thermosetting resin film and the protrusion property of the bump top portion.

In the present specification, the “protrusion property of bump top portion” refers to the performance of a bump to penetrate a thermosetting resin film when the thermosetting resin film for forming a protective film is attached to a wafer with the bump, and is also referred to as the penetration property of the bump top portion.

The proportions of three or more monomers constituting the poly(vinyl acetal) can be optionally selected.

The content of the polymer component (A) is preferably from 2 to 30 mass %, more preferably from 3 to 25 mass %, and even more preferably from 3 to 15 mass % based on the total amount of the active components of the thermosetting resin composition.

The polymer component (A) may also correspond to the thermosetting component (B). In the present embodiment, in a case where the thermosetting resin composition contains such a component corresponding to both the polymer component (A) and the thermosetting component (B), the thermosetting resin composition is regarded as containing both the polymer component (A) and the thermosetting component (B).

### Thermosetting Component (B)

The thermosetting resin film and the thermosetting resin composition contain the thermosetting component (B).

The thermosetting component (B) is a component for curing the thermosetting resin film to form a hard cured resin film.

One thermosetting component (B) may be used alone or two or more thermosetting components (B) may be used in combination. When two or more thermosetting components (B) are used, their combination and proportions can be optionally selected.

Examples of the thermosetting component (B) include epoxy-based thermosetting resins, thermosetting polyimides, polyurethanes, unsaturated polyesters, and silicone resins. Among these, an epoxy-based thermosetting resin is preferred. When the thermosetting component (B) is an epoxy-based thermosetting resin, it is possible to improve the protection of the cured resin film and the protrusion property of the bump top portion, and suppress warpage of the cured resin film.

The epoxy-based thermosetting resin contains an epoxy resin (B1) and a thermal curing agent (B2).

One epoxy-based thermosetting resin may be used alone, or two or more epoxy-based thermosetting resins may be used in combination. When two or more epoxy-based thermosetting resins are used, their combination and proportions can be optionally selected.

### Epoxy Resin (B1)

The epoxy resin (B1) is not particularly limited, but from the viewpoint of more easily exhibiting the effects of the present invention, an epoxy resin that is a solid at normal temperature (hereinafter, also referred to as a solid epoxy resin) and an epoxy resin that is a liquid at normal temperature (hereinafter, also referred to as a liquid epoxy resin) are preferably used in combination.

In the present specification, “normal temperature” refers to 5 to 35° C., and preferably 15 to 25° C.

The liquid epoxy resin is not particularly limited as long as it is a liquid at normal temperature, and examples thereof include a bisphenol A type epoxy resin, a bisphenol F type epoxy resin, a novolak type epoxy resin, a glycidyl ester type epoxy resin, a biphenyl type epoxy resin, and a phenylene skeleton type epoxy resin. Among these, a bisphenol A type epoxy resin is preferred.

One liquid epoxy resin may be used alone, or two or more liquid epoxy resins may be used in combination. When two or more liquid epoxy resins are used, their combination and proportions can be optionally selected.

The epoxy equivalent of the liquid epoxy resin is preferably 200 to 600 g/eq, more preferably 250 to 550 g/eq, and even more preferably 300 to 500 g/eq.

The epoxy equivalent in the present embodiment can be measured in accordance with JIS K 7236:2009.

The solid epoxy resin is not particularly limited as long as it is a solid at normal temperature, and examples thereof include a biphenyl type epoxy resin, a bisphenol A type epoxy resin, a bisphenol F type epoxy resin, an orthocresol novolak epoxy resin, a dicyclopentadiene type epoxy resin, a naphthalene type epoxy resin, an anthracene type epoxy resin, and a fluorene-based epoxy resin. Among these, a naphthalene type epoxy resin, a dicyclopentadiene type epoxy resin, and a fluorene-based epoxy resin are preferred, and a naphthalene type epoxy resin and a dicyclopentadiene type epoxy resin are more preferred.

One solid epoxy resin may be used alone, or two or more solid epoxy resins may be used in combination. When two or more solid epoxy resins are used, their combination and proportions can be optionally selected.

The epoxy equivalent of the solid epoxy resin is preferably 150 to 450 g/eq, and more preferably 150 to 400 g/eq.

The ratio [(x)/(y)] of the content of the liquid epoxy resin (x) to the content of the solid epoxy resin (y) is preferably 0.01 to 10.0, more preferably 0.02 to 8.0, and even more preferably 0.03 to 6.0 in terms of mass ratio. When the ratio [(x)/(y)] is within the above range, generation of cutting debris can be suppressed when the cured resin film after curing is cut with a dicing blade, whereby processability can be easily improved.

The number average molecular weight of the epoxy resin (B1) is not particularly limited, but from the viewpoint of the curing property of the thermosetting resin film and the strength and heat resistance of the cured resin film after curing, the number average molecular weight is preferably from 300 to 30000, more preferably from 400 to 10000, and even more preferably from 500 to 3000.

### Thermal Curing Agent (B2)

The thermal curing agent (B2) functions as a curing agent for the epoxy resin (B1).

Examples of the thermal curing agent (B2) include a compound having two or more functional groups that can react with an epoxy group per molecule. Examples of the functional group include a phenolic hydroxyl group, an alcoholic hydroxyl group, an amino group, a carboxy group, and a group formed by dehydration of an acid group, and the functional group is preferably a phenolic hydroxyl group, an amino group, or a group formed by dehydration of an acid group, and more preferably a phenolic hydroxyl group or an amino group.

Among the thermal curing agents (B2), examples of the phenol-based curing agent having a phenolic hydroxyl group include multifunctional phenolic resins, biphenol, novolak-type phenolic resins, dicyclopentadiene-based phenolic resins, and aralkyl phenolic resins.

Among the thermal curing agents (B2), examples of the amine-based curing agent having an amino group include dicyandiamide (which may be hereinafter abbreviated as “DICY”).

Among these, a phenol-based curing agent having a phenolic hydroxyl group is preferred, and a novolak-type phenolic resin is more preferred.

The number average molecular weight of a resin component, for example, a multifunctional phenolic resin, a novolak-type phenolic resin, a dicyclopentadiene-based phenolic resin, or an aralkyl phenolic resin, among the thermal curing agents (B2) is preferably from 300 to 30000, more preferably from 400 to 10000, and even more preferably from 500 to 3000.

The molecular weight of the non-resin component, for example, bisphenol or dicyandiamide, among the thermal curing agents (B2) is not particularly limited, but is, for example, preferably from 60 to 500.

One thermal curing agent (B2) may be used alone, or two or more thermal curing agents (B2) may be used in combination. When two or more thermal curing agents (B2) are used, their combination and proportions can be optionally selected.

In the thermosetting resin composition, the content of the thermal curing agent (B2) is preferably from 0.010 to 200 parts by mass, more preferably from 0.020 to 150 parts by mass, even more preferably from 0.050 to 100 parts by mass, and still even more preferably from 0.10 to 77 parts by mass per 100 parts by mass of the content of the epoxy resin (B1). When the content of the thermal curing agent (B2) is the lower limit described above or more, the curing of the thermosetting resin film is more likely to proceed. Meanwhile, when the content of the thermal curing agent (B2) is the upper limit described above or less, the moisture absorption rate of the thermosetting resin film is reduced, and the reliability of a package produced using the thermosetting resin film is further improved.

In the thermosetting resin composition, the content of the thermosetting component (B) (the total content of the epoxy resin (B1) and the thermal curing agent (B2)) is preferably from 200 to 10000 parts by mass, more preferably from 300 to 5000 parts by mass, even more preferably from 400 to 2000 parts by mass, and still even more preferably from 500 to 1000 parts by mass with respect to 100 parts by mass of the content of the polymer component (A), from the viewpoint of enhancing the protection of the cured resin film.

### Curing Accelerator (C)

The thermosetting resin film and the thermosetting resin composition may contain a curing accelerator (C).

The curing accelerator (C) is a component for adjusting the curing rate of the thermosetting resin composition.

Examples of preferred curing accelerators (C) include tertiary amines, such as triethylenediamine, benzyldimethylamine, triethanolamine, dimethylaminoethanol, and tris(dimethylaminomethyl) phenol; imidazoles (imidazoles in which one or more hydrogen atoms are replaced by groups other than hydrogen atoms), such as 2-methylimidazole, 2-phenylimidazole, 2-phenyl-4-methylimidazole, 2-phenyl-4,5-dihydroxymethylimidazole, and 2-phenyl-4-methyl-5-hydroxymethylimidazole; organic phosphines (phosphines in which one or more hydrogen atoms are replaced by organic groups), such as tributylphosphine, diphenylphosphine, and triphenylphosphine; and tetraphenylboron salts, such as tetraphenylphosphonium tetraphenylborate and triphenylphosphine tetraphenylborate.

Among these, from the viewpoint of allowing the effects of the present invention to be exhibited more easily, the curing accelerator (C) is preferably an imidazole, and more preferably 2-phenyl-4,5-dihydroxymethylimidazole.

One curing accelerator (C) may be used alone, or two or more curing accelerators (C) may be used in combination. When two or more curing accelerators (C) are used, their combination and proportions can be optionally selected.

When the curing accelerator (C) is used in the thermosetting resin composition, the content of the curing accelerator (C) is preferably from 0.001 to 10 parts by mass, and more preferably from 0.01 to 5 parts by mass per 100 parts by mass of the content of the thermosetting component (B). When the content of the curing accelerator (C) is the lower limit described above or more, the effect of using the curing accelerator (C) is more remarkably achieved. Meanwhile, when the content of the curing accelerator (C) is the upper limit described above or less, the curing accelerator (C) having high polarity is effectively prevented from moving in the thermosetting resin film toward the adhesive interface with an adherend and from segregating therein under high temperature and high humidity conditions, and thus the reliability of a package produced using the thermosetting resin film is further improved.

### Filler (D)

The thermosetting resin film and the thermosetting resin composition may contain a filler (D).

When the filler (D) is contained, the thermal expansion coefficient of the cured resin film obtained by curing the thermosetting resin film is easily adjusted to fall within an appropriate range, and the reliability of a package obtained using the thermosetting resin film is further improved. In addition, when the thermosetting resin film contains the filler (D), the moisture absorption rate of the cured resin film can be reduced, and the heat dissipation can be improved.

The filler (D) may be either an organic filler or an inorganic filler, but is preferably an inorganic filler. Examples of preferred inorganic fillers include powders, such as those of silica, talc, calcium carbonate, and boron nitride; beads prepared by spheronization of such an inorganic filler; surface-modified products of these inorganic fillers; single crystal fibers of these inorganic fillers; and glass fibers. Among these, the inorganic filler is preferably silica.

One filler (D) may be used alone, or two or more fillers (D) may be used in combination.

When two or more fillers (D) are used, their combination and proportions can be optionally selected.

When the filler (D) is used, the content of the filler (D) is preferably from 5 to 50 mass %, more preferably from 7 to 40 mass %, and even more preferably from 10 to 30 mass % based on the total amount of the active components of the thermosetting resin composition, from the viewpoint of suppressing peeling of the cured resin film from the chip due to thermal expansion and thermal contraction.

The average particle size of the filler (D) is preferably from 5 nm to 1000 nm, more preferably from 5 nm to 500 nm, and even more preferably from 10 nm to 300 nm.

In the present specification, the particle size of the filler (D) means an arithmetic average particle size obtained by averaging the particle sizes of a plurality of randomly selected primary particles of the filler (D) as observed and measured with an electron microscope.

### Energy Ray-Curable Resin (E)

The thermosetting resin film and the thermosetting resin composition may contain an energy ray-curable resin (E).

When the thermosetting resin film contains the energy ray-curable resin (E), the properties of the film can be varied by energy ray irradiation.

The energy ray-curable resin (E) is formed by polymerizing (curing) an energy ray-curable compound. Examples of the energy ray-curable compound include a compound having at least one polymerizable double bond in the molecule, and an acrylate-based compound having a (meth)acryloyl group is preferred.

Examples of the acrylate-based compound include chain aliphatic backbone-containing (meth)acrylates, such as trimethylolpropane tri (meth)acrylate, tetramethylolmethane tetra(meth)acrylate, pentaerythritol tri (meth)acrylate, pentaerythritol tetra(meth)acrylate, dipentaerythritol monohydroxy penta (meth)acrylate, dipentaerythritol hexa (meth)acrylate, 1,4-butylene glycol di(meth)acrylate, and 1,6-hexanediol di(meth)acrylate; cycloaliphatic backbone-containing (meth)acrylates, such as dicyclopentanyl di(meth)acrylate; poly(alkylene glycol) (meth)acrylates, such as polyethylene glycol di(meth)acrylate; oligoester (meth)acrylates; urethane (meth)acrylate oligomers; epoxy-modified (meth)acrylates; polyether (meth)acrylates other than the poly(alkylene glycol) (meth)acrylates; and itaconic acid oligomers.

The weight average molecular weight of the energy ray-curable compound is preferably from 100 to 30000, and more preferably from 300 to 10000.

One energy ray-curable compound may be used alone, or two or more energy ray-curable compounds may be used in combination for polymerization. When two or more energy ray-curable compounds are used for polymerization, their combination and proportions can be optionally selected.

When the energy ray-curable resin (E) is used, the content of the energy ray-curable resin (E) is preferably from 1 to 95 mass %, more preferably from 5 to 90 mass %, and even more preferably from 10 to 85 mass % based on the total amount of the active components of the thermosetting resin composition.

### Photopolymerization Initiator (F)

In a case where the thermosetting resin film and the thermosetting resin composition contain the energy ray-curable resin (E), the thermosetting resin film and the thermosetting resin composition may contain a photopolymerization initiator (F) to facilitate efficient polymerization reaction of the energy ray-curable resin (E).

Examples of the photopolymerization initiator (F) include benzophenone, acetophenone, benzoin, benzoin methyl ether, benzoin ethyl ether, benzoin isopropyl ether, benzoin isobutyl ether, benzoin benzoate, methyl benzoin benzoate, benzoin dimethyl ketal, 2,4-diethylthioxanthone, 1-hydroxycyclohexyl phenyl ketone, benzyldiphenyl sulfide, tetramethylthiuram monosulfide, azobisisobutyronitrile, benzyl, dibenzyl, diacetyl, 1,2-diphenylmethane, 2-hydroxy-2-methyl-1-[4-(1-methylvinyl)phenyl]propanone, 2,4,6-trimethylbenzoyldiphenylphosphine oxide, and 2-chloroanthraquinone.

One photopolymerization initiator (F) may be used alone, or two or more photopolymerization initiators (F) may be used in combination. When two or more photopolymerization initiators (F) are used, their combination and proportions can be optionally selected.

In the thermosetting resin composition, the content of the photopolymerization initiator (F) is preferably from 0.1 to 20 parts by mass, more preferably from 1 to 10 parts by mass, and even more preferably from 2 to 5 parts by mass per 100 parts by mass of the content of the energy ray-curable resin (E).

### Near-Infrared Shielding Particles (G)

As described above, from the viewpoint of easily satisfying requirement (1) above, the thermosetting resin film and the thermosetting resin composition preferably contain near-infrared shielding particles (G).

Examples of the near-infrared shielding particles (G) include those exemplified above as the near-infrared shielding particles, and among them, a black pigment (G1) is preferred.

The preferred black pigment (G1) and the content of the black pigment (G1) are as described above.

### Additive (H)

The thermosetting resin film and the thermosetting resin composition may contain an additive (H) as long as the effects of the present invention are not impaired. The additive (H) is not particularly limited, and may be any known additive and can be optionally selected depending on the purpose.

Preferred examples of the additive (H) include a coupling agent, a crosslinking agent, a surfactant, a plasticizer, an antistatic agent, an antioxidant, a leveling agent, and a gettering agent.

One additive (H) may be used alone, or two or more additives (H) may be used in combination. When two or more versatile additives (H) are used, their combination and proportions can be optionally selected.

The content of the additive (H) is not particularly limited and only needs to be appropriately selected depending on the purpose.

### Solvent

Preferably, the thermosetting resin composition further contains a solvent.

The thermosetting resin composition containing a solvent has good handleability.

The solvent is not particularly limited, but preferred examples include hydrocarbons, such as toluene and xylene; alcohols, such as methanol, ethanol, 2-propanol, isobutyl alcohol (2-methylpropan-1-ol), and 1-butanol; esters, such as ethyl acetate; ketones, such as acetone and methyl ethyl ketone; ethers, such as tetrahydrofuran; and amides (compounds having an amide bond), such as dimethylformamide and N-methylpyrrolidone.

One solvent may be used alone, or two or more solvents may be used in combination. When two or more solvents are used, their combination and proportions can be optionally selected.

The solvent is preferably methyl ethyl ketone from the viewpoint that components contained in the thermosetting resin composition can be more uniformly mixed.

### Method for Preparing Thermosetting Resin Composition

The thermosetting resin composition is prepared by blending the components for constituting the composition.

The order of adding the components during blending is not particularly limited, and two or more components may be added simultaneously. When a solvent is used, the solvent may be used by mixing with any of the components to be blended other than the solvent to preliminarily dilute the component to be blended, or the solvent may be used by mixing with these components to be blended without preliminarily diluting any of the components to be blended other than the solvent.

The method of mixing the components during blending is not particularly limited and is appropriately selected from known methods, such as a method of mixing by rotating a stirring bar or a stirring blade; a method of mixing using a mixer; and a method of mixing by applying an ultrasonic wave.

The temperature and time when the components are added and mixed are not particularly limited as long as each of the blended components is not degraded, and are appropriately controlled. The temperature is preferably from 15 to 30° C.

### Composite Sheet

The curable resin film of the present embodiment can constitute a composite sheet having a laminated structure in which the curable resin film and a release sheet are laminated. When the curable resin film constitutes the composite sheet, the curable resin film is stably supported and protected when the curable resin film is transported as a product package or when the curable resin film is conveyed in a production process of a semiconductor chip.

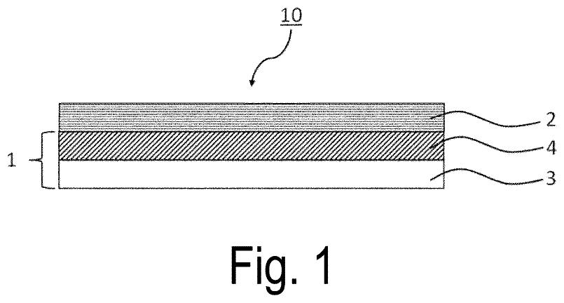

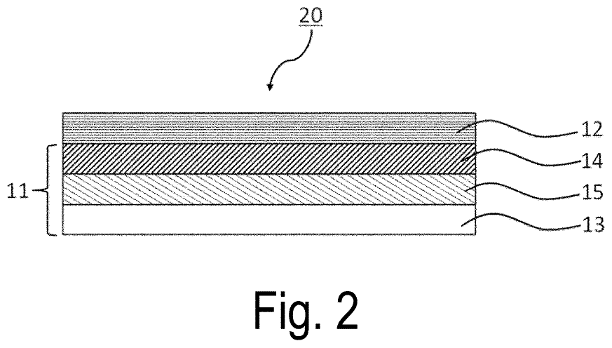

FIG. 1 is a schematic cross-sectional view illustrating a configuration of a composite sheet according to an embodiment, and FIG. 2 is a schematic cross-sectional view illustrating a configuration of a composite sheet according to another embodiment. A composite sheet 10 of FIG. 1 includes a release sheet 1 and a curable resin film 2 provided on the release sheet 1. The release sheet 1 includes a substrate 3 and a release layer 4, and the release layer 4 is provided to face the curable resin film 2.

A composite sheet 20 of FIG. 2 includes a release sheet 11 and a curable resin film 12 provided on the release sheet 11. The release sheet 11 may include an intermediate layer 15 provided between a substrate 13 and a release layer 14.

The laminate in which the substrate 13, the intermediate layer 15, and the release layer 14 are laminated in this order is suitable for use as a back grinding sheet.

The respective layers constituting the release sheet used in the composite sheet according to the present embodiment will be described below.

### Substrate

The substrate is in the form of sheet or film, and examples of its constitutional material include various resins below.

Examples of the resin constituting the substrate include polyethylenes, such as low-density polyethylene (LDPE), linear low-density polyethylene (LLDPE), and high-density polyethylene (HDPE); polyolefins other than polyethylenes, such as polypropylene, polybutene, polybutadiene, polymethylpentene, and norbornene resins; ethylene-based copolymers (copolymers formed using ethylene as a monomer), such as ethylene-vinyl acetate copolymers, ethylene-(meth)acrylic acid copolymers, ethylene-(meth)acrylic ester copolymers, and ethylene-norbornene copolymers; vinyl chloride-based resins (resins formed by using vinyl chloride as a monomer), such as poly(vinyl chloride) and vinyl chloride copolymers; polystyrenes; polycycloolefins; polyesters, such as poly(ethylene terephthalate), poly(ethylene naphthalate), poly(butylene terephthalate), poly(ethylene isophthalate), poly(ethylene-2,6-naphthalane dicarboxylate), and wholly aromatic polyesters in which all the constitutional units have an aromatic cyclic group; copolymers of two or more types of polyesters described above; poly(meth)acrylic esters; polyurethanes; poly(urethane acrylate); polyimides; polyamides; polycarbonates; fluororesins; polyacetals; modified poly(phenylene oxide); poly(phenylene sulfide); polysulfones; and poly(ether ketone).

Examples of the resin constituting the substrate also include polymer alloys, such as a mixture of the polyester described above and a resin other than the polyester. The polymer alloy of the polyester and a resin other than the polyester preferably contains a relatively small amount of the resin other than the polyester.

Examples of the resin constituting the substrate also include crosslinked resins in which one or two or more of the resins exemplified so far are crosslinked; and modified resins, such as ionomers formed using one or two or more of the resins exemplified so far.

One resin constituting the substrate may be used alone, or two or more resin constituting the substrate may be used in combination. When two or more resins constitute the substrate, their combination and proportions can be optionally selected.

The substrate may be composed of only one layer (single layer) or may be composed of a plurality of layers; i.e., two or more layers. When the substrate is composed of a plurality of layers, these layers may be identical to or different from one another, and the combination of these layers is not particularly limited.

The thickness of the substrate is preferably from 5 μm to 1000 μm, more preferably from 10 μm to 500 μm, even more preferably from 15 μm to 300 μm, and still more preferably from 20 μm to 150 μm.

Here, the “thickness of the substrate” means the thickness of the entire substrate; for example, the thickness of a substrate composed of a plurality of layers means the total thickness of all layers composing the substrate.

Preferably, the substrate is highly precise in its thickness, that is, a variation in thickness is small in any portion of the substrate. Examples of such a material highly precise in thickness, which can be used for forming the substrate, among the constitutional materials described above, include polyethylene, polyolefins other than polyethylene, poly(ethylene terephthalate), poly(butylene terephthalate), and ethylene-vinyl acetate copolymers.

The substrate may contain any known type of additive, such as a filler, a colorant, an antistatic agent, an antioxidant, an organic lubricant, a catalyst, or a softener (plasticizer), in addition to the primary constitutional materials, such as the resin.

The substrate may be transparent or opaque, or may be colored depending on the purpose, or alternatively another layer may be vapor-deposited on the substrate.

The substrate can be manufactured by a known method. For example, a resin-containing substrate can be manufactured by molding a resin composition containing the resin described above.

### Release Layer

The release layer has a function of imparting releasability to the release sheet. The release layer is formed of, for example, a cured product of a release layer-forming composition containing a release agent.

The release agent is not particularly limited, and examples thereof include silicone resins, alkyd resins, acrylic resins, and ethylene-vinyl acetate copolymers. Among these, an ethylene-vinyl acetate copolymer is preferred from the viewpoint of enhancing the protrusion property of the bump top portion and from the viewpoint of the releasability from the cured resin film.

The release layer may be composed of only one layer (single layer) or may be composed of a plurality of layers; i.e., two or more layers. When the release layer is composed of a plurality of layers, these layers may be identical to or different from one another, and the combination of these layers is not particularly limited.

From the viewpoint of releasability and handling property, the thickness of the release layer is preferably from 3 to 50 μm and more preferably from 5 to 30 μm. Here, the “thickness of the release layer” means the thickness of the entire release layer, and for example, the thickness of the release layer composed of a plurality of layers means the total thickness of all the layers constituting the release layer.

### Intermediate Layer

The intermediate layer is in the form of a sheet or film, and the constitutional material is appropriately selected depending on the purpose and is not particularly limited. For example, the shape of the bump present on the semiconductor surface may be reflected on the protective film covering the semiconductor surface, and this may cause deformation of the cured resin film. When the purpose is to prevent such deformation of the cured resin film, examples of a preferred constitutional material of the intermediate layer include urethane (meth)acrylates; and a resin containing a constitutional unit derived from a monomer component such as an olefin-based monomer such as an α-olefine, from the viewpoints of achieving high conformability to unevenness and further improving attachability of the intermediate layer.

The intermediate layer may be composed of only one layer (single layer) or may be composed of a plurality of layers; i.e., two or more layers. When the intermediate layer is composed of a plurality of layers, these layers may be identical to or different from one another, and the combination of these layers is not particularly limited.

The thickness of the intermediate layer can be appropriately adjusted in accordance with the height of the bump of the semiconductor surface to be protected, but is preferably from 50 μm to 600 μm, more preferably from 70 μm to 500 μm, and even more preferably from 80 μm to 400 μm, from the viewpoint that the effect of bumps having a relatively large height can also be easily absorbed. Here, the “thickness of the intermediate layer” means the thickness of the entire intermediate layer; for example, the thickness of an intermediate layer composed of a plurality of layers means the total thickness of all layers constituting the intermediate layer.

### Method for Manufacturing Composite Sheet

The composite sheet can be manufactured by sequentially laminating the layers described above according to the corresponding positional relationship.

For example, in a case where the release layer or the intermediate layer is laminated on the substrate for manufacturing the composite sheet, the release layer or the intermediate layer can be laminated by coating the substrate with a composition for forming a release layer or a composition for forming an intermediate layer, followed by optional drying or irradiation with an energy ray.

Examples of the coating method include spin coating, spray coating, bar coating, knife coating, roll coating, roll knife coating, blade coating, die coating, and gravure coating.

Meanwhile, for example, in a case where the thermosetting resin film is further laminated on the release layer already laminated on the substrate, the thermosetting resin composition is applied onto the release layer, whereby the curable resin film can be directly formed.

Likewise, in a case where the release layer is further laminated on the intermediate layer already laminated on the substrate, a composition for forming a release layer is applied onto the intermediate layer, whereby the release layer can be directly formed.

In a case where a continuous two-layer laminated structure is formed using any of the compositions in this way, a composition is further applied onto the layer formed from the aforementioned composition, whereby a layer can be newly formed. However, the continuous two-layer laminated structure is formed preferably by the following procedure: among the two layers in the laminated structure, the layer to be laminated later is formed in advance on another release film using the composition; and an exposed surface of this formed layer, the exposed surface being opposite to the side in contact with the release film, is bonded to an exposed surface of another layer already formed. In this case, the composition is preferably applied onto a release-treated surface of the release film. The release film is removed as necessary after formation of the laminated structure.

### First Semiconductor Chip Manufacturing Method

The first semiconductor chip manufacturing method according to the present embodiment is a method for manufacturing a semiconductor chip using the curable resin film described above, and is applied when a cured resin film as a protective film is formed on both a bump-formed surface and a side surface of a semiconductor chip having the bump-formed surface provided with a bump. The first semiconductor chip manufacturing method roughly includes step (S1): preparing a semiconductor chip-producing wafer; step (S2): attaching a curable resin film; step (S3): curing the curable resin film; and step (S4): singulating into individual pieces, and further includes step (S-BG): grinding a back surface of the semiconductor chip-producing wafer.

In detail, the first semiconductor chip manufacturing method of the present embodiment includes the following steps (S1) to (S4) in this order:
step (S1): preparing a semiconductor chip-producing wafer in which grooves as predetermined singulation lines are formed in a bump-formed surface of a semiconductor wafer having the bump-formed surface provided with bumps, the grooves not reaching a back surface of the semiconductor wafer;
step (S2): attaching the curable resin film by pressing to the bump-formed surface of the semiconductor chip-producing wafer to cover the bump-formed surface of the semiconductor chip-producing wafer with the curable resin film and to embed the curable resin film into the grooves formed in the semiconductor chip-producing wafer;
step (S3): curing the curable resin film to yield a semiconductor chip-producing wafer having a cured resin film; and
step (S4): singulating the semiconductor chip-producing wafer having the cured resin film along the predetermined singulation lines into individual pieces to produce a semiconductor chip in which at least the bump-formed surface and a side surface are covered with the cured resin film.

The method further includes the following step (S-BG) after step (S2) and before step (S3), after step (S3) and before step (S4), or in step (S4):
step (S-BG): grinding the back surface of the semiconductor chip-producing wafer.

The first semiconductor chip manufacturing method according to the present embodiment can manufacture a semiconductor chip in which both the bump-formed surface and the side surface are covered with and protected by the cured resin film, and the near-infrared shielding performance is imparted to both the bump-formed surface and the side surface by the cured resin film.

The term “covered” here means that the cured resin film is formed along the shape of one semiconductor chip on at least the bump-formed surface and the side surface of the semiconductor chip. That is, the present invention clearly differs from the sealing technique, which confines a plurality of semiconductor chips in a resin.

The first semiconductor chip manufacturing method of the present embodiment will next be described in detail for each step.

In the following description, the “semiconductor chip” is also referred to simply as the “chip”, and the “semiconductor wafer” is also referred to simply as the “wafer”.

In the following description, the curable resin film (curable resin film of the present embodiment) for forming the cured resin film as a protective film on both the bump-formed surface and the side surface of the semiconductor chip is also referred to as a “curable resin film (X1)”. A cured resin film formed by curing the “curable resin film (X1)” is also referred to as a “cured resin film (r1)”. A curable resin film for forming a cured resin film as a protective film on a surface (back surface) of the semiconductor chip opposite to the bump-formed surface is also referred to as a “back surface curable resin film (X2)”. A cured resin film formed by curing the “back surface curable resin film (X2)” is also referred to as a “back surface cured resin film (r2)”.

A composite sheet for forming the cured resin film (r1) as a protective film on both the bump-formed surface and the side surface of the semiconductor chip is also referred to as a “first composite sheet (α1)”. The “first composite sheet (α1)” has a laminated structure in which a “first release sheet (Y1)” and the “curable resin film (X1)” are laminated.

A composite sheet for forming the back surface cured resin film (r2) as a protective film on the back surface of the semiconductor chip is also referred to as a “second composite sheet (α2)”. The “second composite sheet (α2)” has a laminated structure in which a “second release sheet (Y2)” and the “back surface curable resin film (X2)” are laminated.

### Step (S1)

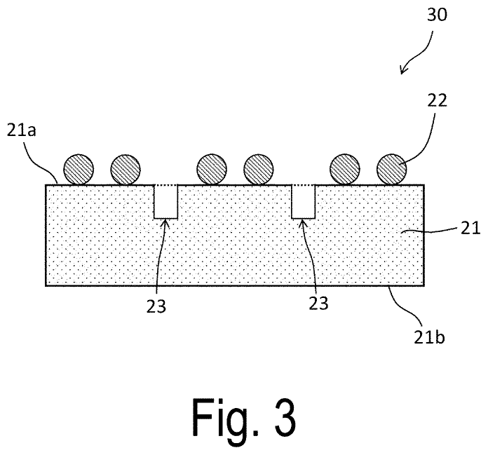

FIG. 3 illustrates a schematic cross-sectional view of an example of the semiconductor wafer prepared in step (S1).

In step (S1), a semiconductor chip-producing wafer 30 is prepared, in which grooves 23 as predetermined singulation lines are formed in a bump-formed surface 21a of a semiconductor wafer 21 having the bump-formed surface 21a provided with bumps 22, the grooves 23 not reaching a back surface 21b.

The shape of each of the bumps 22 is not particularly limited and may be any shape, as long as it can be brought into contact with and fixed to an electrode on a substrate for mounting the chip. For example, the bumps 22 each have a spherical shape in FIG. 3, but the bumps 22 each may be a spheroid. The spheroid may be, for example, a spheroid extending in a direction perpendicular to the bump-formed surface 21a of the wafer 21 or may be a spheroid extending in a direction horizontal to the bump-formed surface 21a of the wafer 21. The bumps 22 each may have a pillar (column) shape.

The height of the bumps 22 is not particularly limited and is appropriately changed according to a design requirement.

The height is, for example, from 30 μm to 300 μm, preferably from 60 μm to 250 μm, and more preferably from 80 μm to 200 μm.

The “height of the bumps 22” means, in view of one bump, the height of a portion of the bump present at the highest position from the bump-formed surface 21a.

The number of the bumps 22 is not particularly limited and is appropriately changed according to a design requirement.

The wafer 21 is a semiconductor wafer in which a circuit of, for example, wiring, a capacitor, a diode, and a transistor is formed on the front surface. The material of the wafer is not particularly limited, and the wafer is, for example, a silicon wafer, a silicon carbide wafer, a compound semiconductor wafer, a glass wafer, or a sapphire wafer.

The size of the wafer 21 is not particularly limited but is typically 8 inches (200 mm in diameter) or greater and preferably 12 inches (300 mm in diameter) or greater from the viewpoint of increasing batch processing efficiency. The shape of the wafer 21 is not limited to a circle and may be, for example, a quadrangle shape, such as a square or a rectangle. In the case where the wafer 21 is a quadrangle-shaped wafer, the length of the longest side is preferably equal to or greater than the size (diameter) described above from the viewpoint of increasing batch processing efficiency.

The thickness of the wafer 21 is not particularly limited but is preferably from 100 μm to 1000 μm, more preferably from 200 μm to 900 μm, and even more preferably from 300 μm to 800 μm from the viewpoint of facilitating prevention of warpage associated with shrinkage when the curable resin film (X1) is cured, and from the viewpoint of reducing a grinding amount of the back surface 21b of the wafer 21 to shorten the time required for grinding of the back surface in a subsequent step.

In the bump-formed surface 21a of the semiconductor chip-producing wafer 30 prepared in step (S1), a plurality of grooves 23 are formed in a lattice pattern as the predetermined singulation lines for singulating the semiconductor chip-producing wafer 30 into individual pieces. The grooves 23 are cut grooves formed when the dicing before grinding method is applied and are formed to have a depth smaller than the thickness of the wafer 21, and thus the deepest portion of the grooves 23 does not reach the back surface 21b of the wafer 21. The grooves 23 can be formed by dicing using a wafer dicing device equipped with a dicing blade known in the related art.

The grooves 23 only need to be formed to allow the semiconductor chip to be manufactured in a desired size and shape. The size of the semiconductor chip is typically about from 0.5 mm×0.5 mm to 1.0 mm×1.0 mm but is not limited to this size.

The width of each of the grooves 23 is preferably from 10 μm to 2000 μm, more preferably from 30 μm to 1000 μm, even more preferably from 40 μm to 500 μm, and still even more preferably from 50 μm to 300 μm from the viewpoint of allowing the curable resin film (X1) to have a good embedding property.

The depth of each of the grooves 23 is adjusted depending on the thickness of the wafer to be used and the required chip thickness and is preferably from 30 μm to 700 μm, more preferably from 60 μm to 600 μm, and even more preferably from 100 μm to 500 μm.

The semiconductor chip-producing wafer 30 prepared in step (S1) is subjected to step (S2).

### Step (S2)

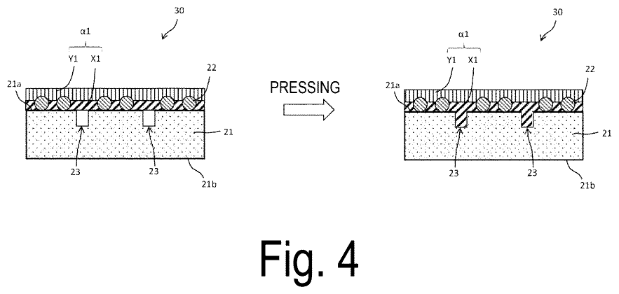

Step (S2) is schematically illustrated in FIG. 4.

In step (S2), the curable resin film (X1) is attached by pressing to the bump-formed surface 21a of the semiconductor chip-producing wafer 30.

Here, from the viewpoint of handleability, the curable resin film (X1) may be used as the first composite sheet (α1) having a laminated structure in which the first release sheet (Y1) and the curable resin film (X1) are laminated. In a case where the first composite sheet (α1) is used, the curable resin film (X1) of the first composite sheet (α1) is attached by pressing, as an attaching surface, to the bump-formed surface 21a of the semiconductor chip-producing wafer 30.

As illustrated in FIG. 4, step (S2) allows the bump-formed surface 21a of the semiconductor chip-producing wafer 30 to be covered with the curable resin film (X1) and allows the curable resin film (X1) to be embedded into the grooves 23 formed in the semiconductor chip-producing wafer 30.

The pressing force when the curable resin film (X1) is attached to the semiconductor chip-producing wafer 30 is preferably from 1 kPa to 200 kPa, more preferably from 5 kPa to 150 kPa, and even more preferably from 10 kPa to 100 kPa from the viewpoint of allowing the curable resin film (X1) to have a good embedding property into the grooves 23.

The pressing force when the curable resin film (X1) is attached to the semiconductor chip-producing wafer 30 may be appropriately changed from the initial stage to the final stage of the attachment. For example, from the viewpoint of allowing the curable resin film (X1) to have a better embedding property into the grooves 23, the pressing force is preferably low at the initial stage of the attachment and is gradually increased.

In a case where the curable resin film (X1) is a thermosetting resin film, heating is preferably performed when the curable resin film (X1) is attached to the semiconductor chip-producing wafer 30, from the viewpoint of allowing the curable resin film (X1) to have a good embedding property into the grooves 23.

Specific heating temperature (attachment temperature) is preferably from 50° C. to 150° C., more preferably from 60° C. to 130° C., and even more preferably from 70° C. to 110° C.

The heating treatment performed on the curable resin film (X1) is not included in the curing treatment of the curable resin film (X1).

Preferably, the curable resin film (X1) is attached to the semiconductor chip-producing wafer 30 in a reduced pressure environment. This creates a negative pressure in the grooves 23 and allows the curable resin film (X1) to be easily distributed in the entire grooves 23. This results in a better embedding property of the curable resin film (X1) into the grooves 23. The specific pressure of the reduced pressure environment is preferably from 0.001 kPa to 50 kPa, more preferably from 0.01 kPa to 5 kPa, and even more preferably from 0.05 kPa to 1 kPa.

### Step (S3)

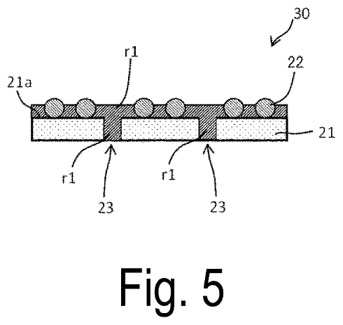

Step (S3) is schematically illustrated in FIG. 5.

In step (S3), the curable resin film (X1) is cured to yield a semiconductor chip-producing wafer 30 having a cured resin film (r1).

The cured resin film (r1) formed by curing the curable resin film (X1) is stronger than the curable resin film (X1) at normal temperature. Thus, the bump neck is well protected by forming the cured resin film (r1).

The curable resin film (X1) can be thermally cured or cured by energy ray irradiation, depending on the type of the curable component contained in the curable resin film (X1).

In the present specification, “energy rays” means electromagnetic waves or charged particle beams having energy quanta; for example, ultraviolet rays or electron beams. Ultraviolet rays are preferred.

For the conditions in a case of the thermal curing, the curing temperature is preferably from 90° C. to 200° C., and the curing time is preferably from 1 hour to 3 hours.

The conditions for curing by energy ray irradiation are appropriately set depending on the type of energy ray to be used. For example, in a case where ultraviolet rays are used, the illuminance is preferably from 170 mW/cm2 to 250 mw/cm2, and the amount of light is preferably from 300 mJ/cm² to 3000 mJ/cm2.

Here, the curable resin film (X1) is preferably a thermosetting resin film from the viewpoint of, during the process of curing the curable resin film (X1) to form the cured resin film (r1), removing air bubbles that may enter into the grooves 23 when the grooves 23 are embedded with the curable resin film (X1) in step (S2).

### Step (S4)

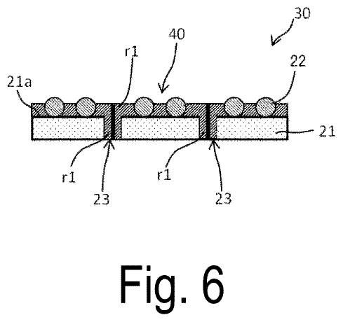

Step (S4) is schematically illustrated in FIG. 6.

In step (S4), portions of the cured resin film (r1) of the semiconductor chip-producing wafer 30 having the cured resin film (r1), the portions being formed in the grooves 23, are cut along the predetermined singulation lines.

The cutting is performed by, for example, blade dicing. This can produce a semiconductor chip 40 in which at least the bump-formed surface 21a and a side surface are covered with the cured resin film (r1).

The semiconductor chip 40 has excellent strength since the bump-formed surface 21a and the side surface are covered with the cured resin film (r1). In addition, the bump-formed surface 21a and the side surface are continuously covered with the cured resin film (r1) without cut lines, and thus the joint surface (interface) between the bump-formed surface 21a and the cured resin film (r1) is not exposed at the side surface of the semiconductor chip 40. Of the joint surface (interface) between the bump-formed surface 21a and the cured resin film (r1), the exposed portion exposed at the side surface of the semiconductor chip 40 is likely to become a starting point of film peeling. Since the exposed portion is not present in the semiconductor chip 40 of the present embodiment, the film peeling from the exposed portion is unlikely to occur in the process of cutting the semiconductor chip-producing wafer 30 to manufacture the semiconductor chip 40 or after manufacturing thereof. Thus, in the semiconductor chip 40 produced, the peeling of the cured resin film (r1) as a protective film is prevented.

Here, in a case where the curable resin film (X1) of the present embodiment contains a black pigment, it becomes possible to clearly recognize unevenness caused by a cut groove (hereinafter, also referred to as “kerf”) defined by each of the grooves 23 on the wafer surface, thereby improving the processability in step (S4). In other words, the black pigment provides the cured resin film (r1) with excellent near-infrared shielding property and improved processability.

The content of the black pigment in the curable resin film is preferably 0.7 mass % or more, more preferably 1.0 mass % or more, and even more preferably 1.5 mass % or more, based on the entire amount of the curable resin film, from the viewpoint of an improvement in the kerf recognition property and an improvement in the near-infrared shielding property.

### Step (S-BG)

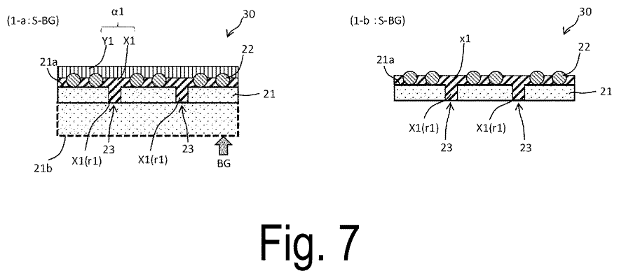

Step (S-BG) is schematically illustrated in FIG. 7.

In step (S-BG), as illustrated in (1-a) of FIG. 7, the back surface 21b of the semiconductor chip-producing wafer 30 is ground in a state where the first composite sheet (α1) is attached. The “BG” in FIG. 7 means back grinding. Then, as illustrated in (1-b) of FIG. 7, the first release sheet (Y1) is peeled off from the first composite sheet (α1).

The amount of grinding the back surface 21b of the semiconductor chip-producing wafer 30 may be such an amount that at least the bottoms of the grooves 23 of the semiconductor chip-producing wafer 30 are exposed, but the back surface 21b may be further ground so that the curable resin film (X1) or the cured resin film (r1) embedded in the grooves 23 is ground together with the semiconductor chip-producing wafer 30.

Although step (S-BG) is performed after step (S2) and before step (S3) in the present embodiment, step (S-BG) may be performed after step (S3) and before step (S4), or may be performed in step (S4).

### Step (TB)

In an aspect of the first semiconductor chip manufacturing method of the present embodiment, the method preferably further includes the following step (TB):
step (TB): forming a back surface protective film on the back surface of the semiconductor chip-producing wafer.

The manufacturing method according to the embodiment described above can produce the semiconductor chip 40 in which at least the bump-formed surface 21a and the side surface are covered with the cured resin film (r1). However, the back surface of the semiconductor chip 40 is uncovered. Thus, step (TB) is preferably performed from the viewpoint of protecting the back surface of the semiconductor chip 40 and further improving the strength of the semiconductor chip 40.

In more detail, step (TB) preferably includes the following steps (TB1) and (TB2) in this order:
step (TB1): attaching the back surface curable resin film (X2) to the back surface of the semiconductor chip-producing wafer; and
step (TB2): curing the back surface curable resin film (X2) to form the back surface cured resin film (r2).

Step (TB1) is performed after step (S-BG). Step (TB2) is performed before step (S4). Thus, in step (S4), the cured resin film-provided semiconductor wafer having the back surface protected with the back surface cured resin film (r2) is singulated into individual pieces to produce a semiconductor chip in which the bump-formed surface and the side surface are protected by the cured resin film (r1) and the back surface is protected by the back surface cured resin film (r2).

In step (TB1), a second composite sheet (α2) having a laminated structure in which the second release sheet (Y2) and the back surface curable resin film (X2) are laminated may be used. In detail, step (TB1) is preferably a step of attaching the second composite sheet (α2) having a laminated structure in which the second release sheet (Y2) and the back surface curable resin film (X2) are laminated to the back surface of the semiconductor chip-producing wafer using the back surface curable resin film (X2) as an attachment surface.

In this case, the timing of peeling off the second release sheet (Y2) from the second composite sheet (α2) may be between step (TB1) and step (TB2) or may be after step (TB2).

Here, in a case where the second composite sheet (α2) is used in step (TB1), the release sheet (Y2) included in the second composite sheet (α2) preferably supports the back surface curable resin film (X2) and also functions as a dicing sheet.

Since the second composite sheet (α2) is attached to the back surface 21b of the semiconductor wafer 30 having the cured resin film (r1) in step (S4), the second release sheet (Y2) functions as a dicing sheet when the semiconductor wafer 30 is singulated into individual pieces by dicing, and the dicing is easily performed.

In a case where step (S3) is performed after step (S-BG), step (TB1) may be performed before performing step (S3), and then step (S3) and step (TB2) may be performed simultaneously. That is, the curable resin film (X1) and the second curable resin film (X2) may be collectively cured simultaneously. This can reduce the number of curing treatments.

### Back Surface Curable Resin Film (X2)

The second curable resin film (X2) may be appropriately a common curable resin film used for forming a back surface protective film of a semiconductor chip, and for example, may be made of the same material and have the same structure as the curable resin film (X1).

However, the back surface of the semiconductor wafer is typically a smooth surface having neither bumps nor grooves, and thus the back surface curable resin film (X2) is not required to satisfy requirement (2), which is a preferable condition for the curable resin film (X1). Thus, in the back surface curable resin (X2), the X value may be 18 or less and may be 10000 or more.

Preferably, the second curable resin film (X2) also satisfies requirement (1) described above, from the viewpoint of imparting the near-infrared shielding performance to the back surface side of the semiconductor chip.

Thus, the second curable resin film (X2) preferably contains the near-infrared shielding particles (G).

Examples of the near-infrared shielding particles (G) include those exemplified above as the near-infrared shielding particles, and among them, a black pigment (G1) is preferred.

The preferable black pigment (G1) and the content of the black pigment (G1) are as described above.

### Step (U)

In an aspect of the first semiconductor chip manufacturing method of the present embodiment, the method may further include step (U) below:
step (U): removing the cured resin film (r1) covering the top of the bump or the cured resin film (r1) adhered to a portion of the top of the bump to expose the top of the bump.

Examples of the exposure treatment for exposing the top of the bump include etching treatment, such as wet etching treatment or dry etching treatment.

Examples of the dry etching treatment include plasma etching treatment.

In a case where the top of the bump is not exposed on the surface of the protective film, the exposure treatment may be performed for the purpose of thinning the protective film until the top of the bump is exposed.

The timing of performing step (U) is not particularly limited as long as step (U) is performed in a state where the cured resin film (r1) is exposed, and step (U) is preferably performed after step (S3) and before step (S4) and in a state where the release sheet (Y1) and the back grinding sheet are not attached.

### Second Semiconductor Chip Manufacturing Method

The semiconductor chip manufacturing method using the curable resin film described above is not limited to a manufacturing method that is applied when a cured resin film as a protective film is formed on both a bump-formed surface and the side surface of a semiconductor chip having the bump-formed surface provided with bumps as in the case of the first semiconductor chip manufacturing method, but may be a manufacturing method that is applied when a cured resin film as a protective film is formed only on a bump-formed surface of a semiconductor chip having the bump-formed surface provided with bumps.

The second semiconductor chip manufacturing method will next be described as a manufacturing method that is applied when a cured resin film as a protective film is formed only on a bump-formed surface of a semiconductor chip having the bump-formed surface provided with bumps.

The second semiconductor chip manufacturing method of the present embodiment includes the following steps (V1) to (V4) in this order:
step (V1): preparing a semiconductor wafer having a bump-formed surface provided with a bump;
step (V2): attaching the aforementioned curable resin film by pressing to the bump-formed surface of the semiconductor wafer to cover the bump-formed surface of the semiconductor wafer with the curable resin film;
step (V3): curing the curable resin film to yield a semiconductor wafer having a cured resin film; and
step (V4): singulating the semiconductor wafer having the cured resin film into individual pieces to produce a semiconductor chip in which the bump-formed surface is covered with the cured resin film.

Examples of the semiconductor wafer prepared in step (V1) include the same semiconductor wafer as the semiconductor wafer 21 having the bump-formed surface 21a provided with the bumps 22 described in step (S1).

Step (V2) is the same as step (S2). When the curable resin film is attached to the bump-formed surface of the semiconductor wafer by pressing, the entire bump-formed surface including the bump neck can be satisfactorily covered with the curable resin film.

Similar to step (S2), the curable resin film (X1) may be used as the first composite sheet (α1) having a laminated structure in which the first release sheet (Y1) and the curable resin film (X1) are laminated, from the viewpoint of handleability.

Step (V3) is the same as step (S3).

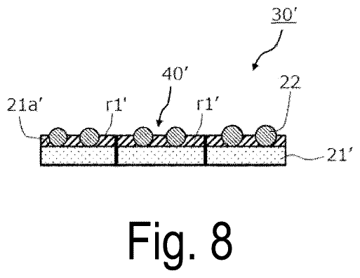

Step (V4) is schematically illustrated in FIG. 8. In FIG. 8, a member corresponding to that illustrated in FIG. 6 schematically illustrating step (S4) of the first semiconductor chip manufacturing method described above is denoted by a reference numeral marked with a prime symbol at the end of the corresponding reference numeral in FIG. 6.

In step (V4), a semiconductor chip-producing wafer 30′ having a first cured resin film (r1′) is singulated into individual pieces by cutting a semiconductor wafer 21′ and the first cured resin film (r1′) along imaginary predetermined singulation lines.

Singulation of the semiconductor wafer having the cured resin film in step (V4) can be performed by any method that is employed for dicing a semiconductor wafer into chips (for example, blade dicing, laser dicing, Stealth Dicing (registered trademark), blade dicing before grinding, or Stealth Dicing before grinding).

Here, the following step (V-BG) may be included after step (V2) and before step (V3), or after step (V3) and before step (V4):
step (V-BG): grinding the back surface of the semiconductor chip-producing wafer.

However, in a case where Stealth Dicing (registered trademark), blade dicing before grinding, or Stealth Dicing before grinding is employed in step (V4), step (V-BG) is preferably performed in step (V4). Thus, singulation of the semiconductor wafer having the cured resin film and thinning of the semiconductor wafer can be simultaneously performed.

The second semiconductor chip manufacturing method of the present embodiment may also include one or both of step (TB) and step (U) described above.

However, in a case where step (TB) is employed, the back surface protective film is formed on the back surface of the semiconductor wafer having a bump-formed surface provided with bumps. Thus, step (TB) is changed to the following step (TA) and then employed:
step (TA): forming a back surface protective film on a back surface of a semiconductor wafer having a bump-formed surface provided with bumps.

In more detail, step (TA) preferably includes the following step (TA1) and step (TA2) in this order:
step (TA1): attaching the back surface curable resin film (X2) to the back surface of the semiconductor wafer; and
step (TA2): curing the back surface curable resin film (X2) to form the back surface cured resin film (r2).

### Semiconductor Chip

The semiconductor chip of the present embodiment has a bump-formed surface provided with bumps, and has a cured resin film formed by curing the curable resin film of the present embodiment on the bump-formed surface.

Thus, according to the present embodiment, there is provided a semiconductor chip having a cured resin film formed by curing the above-described curable resin film on a bump-formed surface of a semiconductor chip having the bump-formed surface provided with bumps, wherein the semiconductor chip is provided with a near-infrared shielding function.

There is also provided a semiconductor chip having a cured resin film formed by curing the curable resin film on a bump-formed surface of a semiconductor chip having the bump-formed surface provided with bumps, and further having a back surface protective film, wherein the semiconductor chip is provided with a near-infrared shielding function.

The semiconductor chip of the present embodiment has a bump-formed surface provided with bumps, and has a cured resin film formed by curing the curable resin film of the present embodiment on both the bump-formed surface and a side surface.

The semiconductor chip of the present embodiment is produced by cutting the cured resin film embedded in the grooves formed in the semiconductor chip-producing wafer along the predetermined singulation lines into individual pieces. The cured resin film is a cured product of the curable resin film.

Thus, according to the present embodiment, there is provided a semiconductor chip having a cured resin film formed by curing the above-described curable resin film on both a bump-formed surface and a side surface of a semiconductor chip having the bump-formed surface provided with bumps, wherein the semiconductor chip is provided with a near-infrared shielding function.

There is also provided a semiconductor chip having a cured resin film formed by curing the curable resin film on both a bump-formed surface and a side surface of a semiconductor chip having the bump-formed surface provided with bumps, and further having a back surface protective film, wherein the semiconductor chip is provided with a near-infrared shielding function.

In a case where both the curable resin film and the back surface curable resin film contain a black pigment, a sense of unity in color is provided between the cured resin film formed by curing the curable resin film and the back surface cured resin film formed by curing the back surface curable resin film, whereby designability can be enhanced. In addition, the near-infrared shielding property can be imparted not only to the bump-formed surface and the side surface of the semiconductor chip, but also to the back surface thereof. That is, it is possible to produce a semiconductor chip having excellent near-infrared shielding property and also having excellent designability.

### EXAMPLES

The present invention will be specifically described with reference to Examples below, but the present invention is not limited to the following Examples.

### 1. Raw Material for Manufacturing Composition for Forming Thermosetting Resin Film

Raw materials used in manufacturing a composition for forming a thermosetting resin film are shown below.

### (1) Polymer Component (A)

(A)-1: poly(vinyl butyral) having constitutional units represented by Formulae (i)-1, (i)-2, and (i)-3 below (“S-LEC BL-10” available from Sekisui Chemical Co., Ltd., weight average molecular weight of 25000, glass transition temperature of 59° C.):

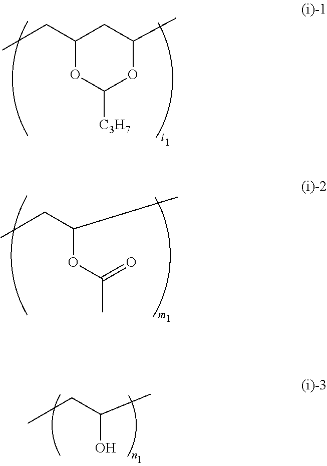

(In the formulae, l₁ is approximately 28, m₁ is from 1 to 3, and n₁ is an integer from 68 to 74.)

(A)-2: polyarylate (“UNIFINER (registered trademark) M-2040” available from UNITIKA LTD.)

(2) Epoxy resin (B1)

### Liquid Epoxy Resin

(B1)-1: liquid modified bisphenol A-type epoxy resin (“EPICLON EXA-4850-150” available from DIC Corporation, number average molecular weight of 900, epoxy equivalent of 450 g/eq)

### Solid Epoxy Resin

(B1)-2: dicyclopentadiene-type epoxy resin (“EPICLON HP-7200HH” available from DIC Corporation, weight average molecular weight of less than 20000, epoxy equivalent of 255 to 260 g/eq)

(B1)-3: naphthalene-type epoxy resin (“EPICLON HP-5000” available from DIC Corporation, epoxy equivalent of 252 g/eq)

(B1)-4: naphthalene-type epoxy resin (“EPICLON HP-4710” available from DIC Corporation, epoxy equivalent of 170 g/eq) (B1)-5: fluorene-type epoxy resin (“OGSOL CG500” available from Osaka Gas Chemical Co., Ltd., epoxy equivalent of 300 g/eq)

### (3) Thermal Curing Agent (B2)

(B2)-1: O-cresol-type novolak resin (“PHENOLITE KA-1160” available from DIC Corporation, hydroxyl group equivalent of 117 g/eq)

### (4) Curing Accelerator (C)

(C)-1: 2-phenyl-4,5-dihydroxymethylimidazole (“CUREZOL 2PHZ-PW” available from Shikoku Chemicals Corporation)

### (5) Filler (D)

(D)-1: spherical silica modified with an epoxy group (“ADMANANO YA050C-MKK” available from Admatechs Company Limited, average particle size of 50 nm)

The average particle size of the filler (D) is an arithmetic average particle size obtained by averaging the particle sizes of a plurality of randomly selected primary particles of a black pigment as observed and measured with an electron microscope.

### (6) Black Pigment (G1)

(G1)-1: carbon black (“MA600B” available from Mitsubishi Chemical Corporation, particle size of 20 nm)

(G1)-2: carbon black (“#20” available from Mitsubishi Chemical Corporation, particle size of 50 nm)

The particle size of the black pigment (G1) is an arithmetic average particle size obtained by averaging the particle sizes of a plurality of randomly selected primary particles of the black pigment as observed and measured with an electronic microscope.

### (7) Additive (H)

(H)-1: surfactant (acrylic polymer, “BYK-361N” available from BYK)

(H)-2: silicone oil (aralkyl-modified silicone oil, “XF42-334” available from Momentive Performance Materials Japan LLC)

### 2. Manufacturing Examples 1 to 12 and Comparative Manufacturing Examples 1 to 8

### 2-1-1. Manufacturing Example 1

### (1) Manufacture of Composition (1) for Forming Thermosetting Resin Film

Components of Blending Formulation 1 shown in Table 1 were dissolved or dispersed in methyl ethyl ketone and stirred at 23° C. to prepare a composition (1) for forming a thermosetting resin film (hereinafter, also referred to simply as “composition (1)”) in which the total concentration of all components other than the solvent was 60 mass %. The blended amount of each of the components other than the solvent shown here is the blended amount of the target product containing no solvent.

### (2) Manufacture of Thermosetting Resin Film

A release film (“SP-PET381031” available from Lintec Corporation, thickness of 38 μm) obtained by release-treating one surface of a poly(ethylene terephthalate) film by silicone treatment was used. The release-treated surface was coated with the composition (1) prepared above and heated and dried for two minutes at 120° C., to thereby form a thermosetting resin film (hereinafter, also referred to as “F (1)-45”) having a thickness of 45 μm.

In the Examples, the thickness of each layer was measured at 23° C. by using a constant-pressure thickness meter (model number: “PG-02J”, standard specifications: in accordance with JIS K 6783:2009, Z 1702:1994, and Z 1709:1995) available from Teclock Co., Ltd.

### 2-1-2. Manufacturing Example 2

A thermosetting resin film (hereinafter, also referred to as “F (1)-10”) having a thickness of 10 μm was formed by the same method as in Manufacturing Example 1 except that the coating amount of the composition (1) was changed.

### 2-1-3. Manufacturing Example 3

A thermosetting resin film (hereinafter, also referred to as “F (1)-5”) having a thickness of 5 μm was formed by the same method as in Manufacturing Example 1 except that the coating amount of the composition (1) was changed.

### 2-1-4. Manufacturing Example 4

A thermosetting resin film (hereinafter, also referred to as “F (2)-45”) having a thickness of 45 μm was formed by the same method as in Manufacturing Example 1 except that Blending Formulation 1 shown in Table 1 was changed to Blending Formulation 2.

### 2-1-5. Manufacturing Example 5

A thermosetting resin film (hereinafter, also referred to as “F (2)-10”) having a thickness of 10 μm was formed by the same method as in Manufacturing Example 4 except that the coating amount of the composition (1) was changed.

### 2-1-6. Manufacturing Example 6

A thermosetting resin film (hereinafter, also referred to as “F (2)-5”) having a thickness of 5 μm was formed by the same method as in Manufacturing Example 4 except that the coating amount of the composition (1) was changed.

### 2-1-7. Manufacturing Example 7

A thermosetting resin film (hereinafter, also referred to as “F (3)-45”) having a thickness of 45 μm was formed by the same method as in Manufacturing Example 1 except that Blending Formulation 1 shown in Table 1 was changed to Blending Formulation 3.

### 2-1-8. Manufacturing Example 8

A thermosetting resin film (hereinafter, also referred to as “F (3)-30”) having a thickness of 30 μm was formed by the same method as in Manufacturing Example 7 except that the coating amount of the composition (1) was changed.

### 2-1-9. Manufacturing Example 9

A thermosetting resin film (hereinafter, also referred to as “F (7)-45”) having a thickness of 45 μm was formed by the same method as in Manufacturing Example 1 except that Blending Formulation 1 shown in Table 1 was changed to Blending Formulation 7.

### 2-1-10. Manufacturing Example 10

A thermosetting resin film (hereinafter, also referred to as “F (7)-10”) having a thickness of 10 μm was formed by the same method as in Manufacturing Example 9 except that the coating amount of the composition (1) was changed.

### 2-1-11. Manufacturing Example 11

A thermosetting resin film (hereinafter, also referred to as “F (8)-45”) having a thickness of 45 μm was formed by the same method as in Manufacturing Example 1 except that Blending Formulation 1 shown in Table 1 was changed to Blending Formulation 8.

### 2-1-12. Manufacturing Example 12

A thermosetting resin film (hereinafter, also referred to as “F (8)-10”) having a thickness of 10 μm was formed by the same method as in Manufacturing Example 11 except that the coating amount of the composition (1) was changed.

### 2-2-1. Comparative Manufacturing Example 1

A thermosetting resin film (hereinafter, also referred to as “F (3)-10”) having a thickness of 10 μm was formed by the same method as in Manufacturing Example 7 except that the coating amount of the composition (1) was changed.

### 2-2-2. Comparative Manufacturing Example 2

A thermosetting resin film (hereinafter, also referred to as “F (3)-5”) having a thickness of 5 μm was formed by the same method as in Manufacturing Example 7 except that the coating amount of the composition (1) was changed.

### 2-2-3. Comparative Manufacturing Example 3

A thermosetting resin film (hereinafter, also referred to as “F (4)-45”) having a thickness of 45 μm was formed by the same method as in Manufacturing Example 1 except that Blending Formulation 1 shown in Table 1 was changed to Blending

### Formulation 4.

### 2-2-4. Comparative Manufacturing Example 4

A thermosetting resin film (hereinafter, also referred to as “F (4)-10”) having a thickness of 10 μm was formed by the same method as in Comparative Manufacturing Example 3 except that the coating amount of the composition (1) was changed.

### 2-2-5. Comparative Manufacturing Example 5

A thermosetting resin film (hereinafter, also referred to as “F (4)-5”) having a thickness of 5 μm was formed by the same method as in Comparative Manufacturing Example 3 except that the coating amount of the composition (1) was changed.

### 2-2-6. Comparative Manufacturing Example 6

A thermosetting resin film (hereinafter, also referred to as “F (5)-45”) having a thickness of 45 μm was formed by the same method as in Manufacturing Example 1 except that Blending Formulation 1 shown in Table 1 was changed to Blending Formulation 5.

### 2-2-7. Comparative Manufacturing Example 7

A thermosetting resin film (hereinafter, also referred to as “F (5)-10”) having a thickness of 10 μm was formed by the same method as in Comparative Manufacturing Example 6 except that the coating amount of the composition (1) was changed.

### 2-2-8. Comparative Manufacturing Example 8

A thermosetting resin film (hereinafter, also referred to as “F (5)-5”) having a thickness of 5 μm was formed by the same method as in Comparative Manufacturing Example 7 except that the coating amount of the composition (1) was changed.

The “-” described in Table 1 corresponding to a component means that each of Blending Formulations 1 to 8 does not contain the component.

TABLE 1

| | | | Blending | Blending | Blending | Blending | Blending | Blending | Blending | Blending |
|---|---|---|---|---|---|---|---|---|---|---|
| | | | Formulation | Formulation | Formulation | Formulation | Formulation | Formulation | Formulation | Formulation |
| | | Unit | 1 | 2 | 3 | 4 | 5 | 6 | 7 | 8 |
| Polymer | (A)-1 | Parts by | 100 | 100 | 100 | 100 | 100 | 100 | — | 100 |
| component | | mass | | | | | | | | |
| (A) | (A)-2 | Parts by | — | — | — | — | — | — | 100 | — |
| | | mass | | | | | | | | |
| Thermosetting | (B1)-1 | Parts by | 288 | 289 | 289 | 375 | 1250 | 289 | 295 | 331 |
| component | | mass | | | | | | | | |
| (B1) | (B1)-2 | Parts by | 221 | 221 | 7812 | 219 | 36 | 2.7 | — | — |
| | | mass | | | | | | | | |
| | (B1)-3 | Parts by | — | — | — | 375 | 750 | 2.7 | — | — |
| | | mass | | | | | | | | |
| | (B1)-4 | Parts by | — | — | — | — | — | — | — | 154 |
| | | mass | | | | | | | | |
| | (B1)-5 | Parts by | — | — | — | — | — | — | 210 | — |
| | | mass | | | | | | | | |
| Thermal | (B2)-1 | Parts by | 165 | 192 | 1.9 | 5.0 | 0.5 | 165 | 162 | 182 |
| curing agent | | mass | | | | | | | | |
| (B2) | | | | | | | | | | |
| Curing | (C)-1 | Parts by | 1.5 | 7.1 | 1.9 | 5.0 | 0.5 | 1.5 | 2.0 | 2.0 |
| accelerator | | mass | | | | | | | | |
| (C) | | | | | | | | | | |
| Filler | (D)-1 | Parts by | 200 | 200 | 200 | 500 | 2000 | 200 | 199 | 199 |
| (D) | | mass | | | | | | | | |
| Black | (G1)-1 | Parts by | — | 50 | 10 | 8.3 | — | 478 | 50 | 50 |
| pigment | | mass | | | | | | | | |
| (G1) | (G1)-2 | Parts by | 50 | — | — | — | — | — | — | — |
| | | mass | | | | | | | | |
| Additive | (H)-1 | Parts by | 22 | 22 | 22 | 56 | 5.0 | 22 | 22 | 22 |
| (H) | | mass | | | | | | | | |
| | (H)-2 | Parts by | 2.4 | 2.5 | 2.5 | 6.3 | 30 | 2.5 | 2.0 | 2.0 |
| | | mass | | | | | | | | |

### 3. Evaluation 1 (Examples 1 to 12 and Comparative Examples 1 to 8)

The thermosetting resin films formed in Manufacturing Examples 1 to 12 and 5 Comparative Manufacturing Examples 1 to 8 were evaluated as described below.

### 3-1. Evaluation of Transmittance

A glass plate (“White Edge Grinding No. 1” available from Matsunami Glass Ind. Ltd., 76 mm long×26 mm wide×1 mm thick) was prepared and cut to half the length for use.

Then, a surface of the thermosetting resin film opposite to a surface on which the release film was provided was attached to the glass plate using a laminator (“Roll-type Laminator RSL-382S” available from Japan Office Laminator Co., Ltd.) under the following conditions.
Attachment temperature: 60° C.
Attachment speed: 1 mm/sec
Attachment pressure: 0.3 MPa

Next, the release film was peeled off from the thermosetting resin film, and the thermosetting resin film was heated under conditions of 130° C. and 0.5 MPa for 240 minutes, and then left to cool to normal temperature (25° C.) to prepare a glass plate having a cured resin film. The transmittances at 940 nm and 800 nm of the glass plate having the cured resin film were measured under the following conditions. When the transmittances were measured, the glass plate having the cured resin film was placed in such a manner that the cured resin film side was a light-receiving surface.
Measuring device: UV-3600 series available from Shimadzu Corporation
Measurement wavelength range: 190 nm to 2000 nm
Detector unit: direct light reception
Measurement temperature: 25° C.

### 3-2. Evaluation 1 of Near-Infrared Shielding Property

The glass plate having the cured resin film prepared in “3.1 Evaluation of Transmittance” was used as a test piece.

The test piece was set at a position 5 cm away from a laser emitting portion of a laser device described below in such a manner that the plane direction of the test piece was perpendicular to the laser emitting direction. The test piece was set in such a manner that the cured resin film side was a laser irradiation surface.
Laser irradiation device: Multi-wavelength laser available from Cobolt (wavelength: 730 nm, 760 nm, 785 nm, 808 nm, 830 nm, 940 nm, 975 nm)
Output wavelength: 940 nm

Next, the test piece was irradiated with a laser having a wavelength of 940 nm, an in-camera of iPhone 7 (available from Apple Inc.) was activated, and the test piece was photographed from a position 10 cm away from the test piece (that is, a position 15 cm away from the laser emitting portion), to thereby evaluate the near-infrared shielding property. The evaluation was carried out at room temperature (23° C.).

A case where the infrared laser was not determined in the in-camera was evaluated as acceptable (A), and a case where the infrared laser was determined in the in-camera was evaluated as unacceptable (F).

In the case where the infrared laser was not determined in the in-camera, it means that the cured resin film has excellent near-infrared shielding property. In contrast, in the case where the infrared laser was determined in the in-camera, it means that the cured resin film has poor near-infrared shielding property.

### 3-3. Evaluation 2 of Near-Infrared Shielding Property

Two PHSs (personal handy-phone systems, available from DoCoMo Co., Ltd., product name “AQUOS”, reception wavelength of 800 nm) were placed with a distance of 15 cm therebetween. Next, the glass plate having the cured resin film prepared in “3.1 Evaluation of Transmittance” was used as a test piece, the test piece was disposed in front of one of the PHSs to block the two PHSs by the test piece, and it was determined whether or not transmission and reception were possible between the two PHSs.

A case where transmission and reception were impossible between the two PHSs was evaluated as acceptable (A), and a case where transmission and reception were possible between the two PHSs was evaluated as unacceptable (F).

In the case where transmission and reception are impossible between the two PHSs, it means that the cured resin film has excellent near-infrared shielding property. In contrast, in the case where transmission and reception are possible between the two PHSs, it means that the cured resin film has poor near-infrared shielding property.

### 4. Evaluation 2 (Examples 1, 4, 7, 9, and 11 and Comparative Examples 3 and 6)

The thermosetting resin films having a thickness of 45 μm formed in Manufacturing Examples 1, 4, 7, 9, and 11 and Comparative Manufacturing Examples 3 and 6 were evaluated as described below.

### 4-1. Measurement of Gc1 and Gc300 of Thermosetting Resin Film and Calculation of X Value

Twenty thermosetting resin films each having a thickness of 45 μm were produced. These thermosetting resin films were then laminated, and the resulting laminated film was cut into a disk having a diameter of 25 mm, to produce a test piece of the thermosetting resin film having a thickness of 1 mm.

The position for placing the test piece in a viscoelasticity measuring device (“MCR301” available from Anton Paar GmbH) was kept warm at 80° C. in advance, and the test piece of the thermosetting resin film produced above was placed in this placing position. A measuring jig was pressed against the upper surface of the test piece to fix the test piece to the placing position.

The strain caused in the test piece was increased stepwise in a range of 0.01% to 1000% under conditions of a temperature of 90° C. and a measurement frequency of 1 Hz, and the storage modulus Gc of the test piece was measured. In addition, the X value was calculated from the measured values of Gc1 and Gc300.

### 4-2. Evaluation of Kerf Recognition Property

(1) Preparation of semiconductor chip-producing wafer

A 12-inch silicon wafer (wafer thickness of 750 μm) in which predetermined singulation lines were half-cut was used as a semiconductor chip-producing wafer. The width of the half-cut portion (width of the groove) of the silicon wafer is 60 μm, and the depth of the groove is 230 μm.

### (2) Evaluation Method

One surface of the thermosetting resin film having a thickness of 45 μm was attached to the front surface side (half-cut-formed surface) of the semiconductor chip-producing wafer while being pressed under the following conditions.
Attachment device: BG tape laminator (“RAD-3510F/8” available from Lintec Corporation)
Attachment pressure: 0.5 MPa
Attachment time: 43 seconds
Attachment speed: 7 mm/sec
Attachment temperature: 80° C.
Roller attachment height: −200 mm

The semiconductor chip-producing wafer having the attached thermosetting resin film was then heated under conditions of 130° C. and 0.5 MPa for 4 hours and cured to form a cured resin film.

Then, the semiconductor chip-producing wafer having the cured resin film was fixed to a dicing table of a dicer (“DFD6362” available from DISCO Corporation), and it was determined whether or not a kerf was recognized by a camera attached to the dicer.

A case where the unevenness of the kerf was clearly recognized was evaluated as acceptable “A”, a case where the unevenness of the kerf was clearly recognized although not so much as in the case of acceptable “A” was evaluated as acceptable “B”, and a case where the unevenness of the kerf was not clearly recognized was evaluated as unacceptable “F”.

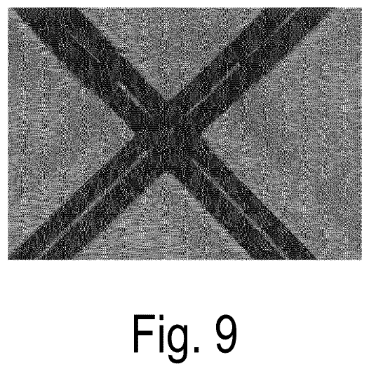

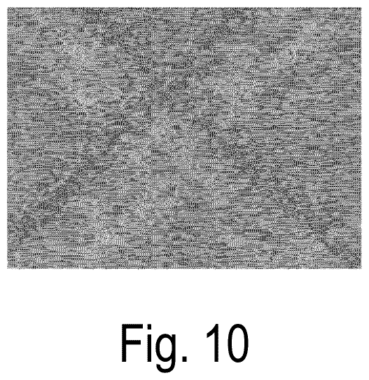

FIG. 9 illustrates an example of an image (photograph) in the case of acceptable “A”, and FIG. 10 illustrates an example of an image (photograph) in the case of unacceptable “B”

### 4-3. Evaluation of Designability and Evaluation of Film Peeling

(1) Production of sample

A back surface of the semiconductor chip-producing wafer having the cured resin film prepared in “4-2. Evaluation of Kerf Recognition Property” was ground, and the thickness of the semiconductor chip-producing wafer was adjusted to 200 μm.

A roll-shaped back surface thermosetting resin film having a thickness of 25 μm sandwiched between release films was attached by using RAD-3600 to the back surface of the semiconductor chip-producing wafer at a table temperature of 70° C. The resultant product was heated at 130° C. for 2 hours to form a back surface cured resin film. DC-tape D-686H (available from Lintec Corporation) was attached to the back surface cured resin film, and the resultant laminate was diced into individual chips having a 6 mm square size by blade dicing along predetermined singulation lines using a blade dicer DFG6362. The chip was peeled off from the DC tape and observed with an optical microscope (“VHX-1000” available from Keyence Corporation).

The roll-shaped back surface thermosetting resin film having a thickness of 25 μm sandwiched between release films was produced by the following procedure.

A polymer component (a), an epoxy resin (b1)-1, an epoxy resin (b1)-2, a curing agent (b2), a curing accelerator (c), a filler (d), a coupling agent (e), and a colorant (J) were dissolved or dispersed in methyl ethyl ketone in such a manner that the contents (solid contents, parts by mass) of these components were 150/70/30/5/2/320/2/18 (solid weight proportions), and stirred at 23° C. to prepare a composition (2) for forming a back surface thermosetting resin film (hereinafter, also simply referred to as “composition (2)”) having a solid concentration of 52 mass %.

(1) Polymer component (a)

An acrylic resin obtained by copolymerization of butyl acrylate (55 parts by mass), methyl acrylate (10 parts by mass), glycidyl methacrylate (20 parts by mass), and 2-hydroxyethyl acrylate (15 parts by mass) (weight average molecular weight of 800000, glass transition temperature of −28° C.).

(2) Epoxy resin (b)

(b1)-1: Bisphenol A-type epoxy resin (jER828 available from Mitsubishi Chemical Corporation, epoxy equivalent of 184 to 194 g/eq)

(b1)-2: Dicyclopentadiene-type epoxy resin (Epiclon HP-7200HH available from DIC Corporation, epoxy equivalent of 255 to 260 g/eq)

### (3) Curing Agent (b2)

Biphenylaralkyl-type phenolic resin (MEHC-7851-H available from Meiwa Plastic Industries, Ltd., hydroxyl group equivalent of 218 g/eq)

### (4) Curing Accelerator (c)

2-Phenyl-4,5-dihydroxymethylimidazole (“CUREZOL 2PHZ-PW” available from Shikoku Chemicals Corporation)

### (5) Filler (d)

Spherical silica modified with an epoxy group (“5SE-CH1” available from Admatechs Company Limited, average particle size of 500 nm)

### (6) Coupling Agent (e)

3-Glycidoxypropyltrimethoxysilane (KBM403 available from Shin-Etsu Chemical Co., Ltd.)

### (7) Colorant (j)

Black pigment (MULTILAC A903 BLACK available from Toyo Ink Co., Ltd.) Next, a release film (“SP-PET381031” available from Lintec Corporation, thickness of 38 μm) obtained by release-treating one surface of a poly(ethylene terephthalate) film by silicone treatment was used. The release-treated surface was coated with the composition (2) produced above, another release film (“SP-PET382150” available from Lintec Corporation) was attached to an exposed surface, and the resultant laminate was then heated and dried for two minutes at 120° C., to thereby form a back surface thermosetting resin film having a thickness of 25 μm sandwiched between the release films. The resultant film was used in the form of a roll for the above-described test.

The designability was evaluated according to the following criteria.

Evaluation “A”: The cured resin film is formed on the entire bump-formed surface and the entire side surface of the semiconductor chip, a sense of unity in color is provided between the cured resin film and the second cured resin film formed on the back surface, and the designability is high.

Evaluation “F”: Although the cured resin film is formed on the entire bump-formed surface and the entire side surface of the semiconductor chip, no sense of unity in color is provided between the cured resin film and the second cured resin film formed on the back surface, and the designability is low.

Film peeling was evaluated according to the following criteria.

Evaluation “A”: The following three conditions are satisfied.

(1) No peeling of the cured resin film from the semiconductor chip is observed on the bump-formed surface and the side surface of the semiconductor chip.

(2) No peeling of the second cured resin film from the semiconductor chip is observed on the back surface of the semiconductor chip.

(3) No peeling between the cured resin film and the second cured resin film is observed.

Evaluation “F”: At least one of the conditions (1) to (3) is not satisfied.

### 4-4. Evaluation of Warpage

A composite sheet including a thermosetting resin film having a thickness of 45 μm formed on a release-treated surface of a release film (“SP-PET381031” available from LINTEC Corporation, thickness of 38 μm) was heat-attached to an κ-inch circularly cut electrolytic copper foil (thickness of 35 μm, available from Kansai Denshi Industries Co., Ltd.) using a table laminator (product name: “LPD3212” available from FUJIPULA) in such a manner that the thermosetting resin film and the copper foil were in contact with each other (attachment pressure of 0.3 MPa, attachment temperature of 60° C., attachment speed of 1 mm/sec, one reciprocation). Next, the thermosetting resin film heat-attached to the copper foil was cut along the circular copper foil with a cutter to prepare a test piece. After visual confirmation of no warpage in the test piece, the release film was peeled off, and the test piece was heat-cured under conditions of a temperature of 130° C. and a pressure of 0.5 MPa for 240 minutes. Thereafter, the test piece was left to cool to normal temperature (25° C.), and then a tape (available from Nichiban Co., Ltd., trade name “Cellotape (registered trademark) LP-24”, tape width of 24 mm) was attached to positions (three positions) obtained by substantially equally dividing, into three parts, the outer periphery of the copper foil to which the thermosetting resin film was heat-attached, and warpage at a predetermined position (position with the largest warpage) was measured. When the warpage was 15 mm or less, it was evaluated as acceptable “A”, whereas when the warpage exceeded 15 mm, it was evaluated as unacceptable “F”.

TABLE 2

| | | | | | Evaluation 1 | | | | | | | | |
|---|---|---|---|---|---|---|---|---|---|---|---|---|---|
| | | | | | Near- | Near- | | | | | | | |
| | Type of | | | | infrared | infrared | Evaluation 2 | | | | | | |
| | thermo- | | Trans- | Trans- | shielding | shielding | | | | Kerf | | | |
| | setting | Black | mittance | mittance | property | property | | | | recog- | | Film | |
| | resin | pigment | at 940 nm | at 800 nm | evaluation | evaluation | Gc1 | Gc300 | | nition | Designa- | peel- | Wafer |
| | film | (mass %) | (%) | (%) | 1 | 2 | (Pa) | (Pa) | X | property | bility | ing | warpage |
| Example 1 | F(1)-45 | 5.0 | 0.001 | 0.001 | A | A | 7812 | 218.5 | 35.8 | A | A | A | A |
| Example 2 | F(1)-10 | 5.0 | 0.076 | 0.079 | A | A | | | | — | — | — | — |
| Example 3 | F(1)-5 | 5.0 | 0.884 | 0.902 | A | A | | | | — | — | — | — |
| Example 4 | F(2)-45 | 5.0 | 0.0001 | 0.001 | A | A | 10280 | 169 | 60.8 | A | A | A | A |
| Example 5 | F(2)-10 | 5.0 | 0.664 | 4.007 | A | A | | | | — | — | — | — |
| Example 6 | F(2)-5 | 5.0 | 2.735 | 21.1345 | A | A | | | | — | — | — | — |
| Example 7 | F(3)-45 | 1.0 | 1.18 | 2.6775 | A | A | 9434 | 129.8 | 72.7 | A | A | A | A |
| Example 8 | F(3)-30 | 1.0 | 10 | 9.89 | A | A | | | | — | — | — | — |
| Example 9 | F(7)-45 | 5.0 | 0.001 | 0.001 | A | A | 19710 | 584 | 33.75 | B | A | A | A |
| Example 10 | F(7)-10 | 5.0 | 0.05 | 0.05 | A | A | | | | — | — | — | — |
| Example 11 | F(8)-45 | 5.0 | 0.001 | 0.001 | A | A | 3240 | 80.7 | 40 | A | A | A | A |
| Example 12 | F(8)-10 | 5.0 | 0.06 | 0.06 | A | A | | | | — | — | — | — |
| Comparative | F(3)-10 | 1.0 | 44 | 53.062 | F | F | 9434 | 129.8 | 72.7 | — | — | — | — |
| Example 1 | | | | | | | | | | | | | |
| Comparative | F(3)-5 | 1.0 | 60 | 76.3835 | F | F | | | | — | — | — | — |
| Example 2 | | | | | | | | | | | | | |
| Comparative | F(4)-45 | 0.5 | 13 | 6.7175 | F | A | 12710 | 49.7 | 255.7 | B | A | A | A |
| Example 3 | | | | | | | | | | | | | |
| Comparative | F(4)-10 | 0.5 | 71 | 71.003 | F | F | | | | — | — | — | — |
| Example 4 | | | | | | | | | | | | | |
| Comparative | F(4)-5 | 0.5 | 82 | 97.3625 | F | F | | | | — | — | — | — |
| Example 5 | | | | | | | | | | | | | |
| Comparative | F(5)-45 | 0.0 | 93 | 87 | F | F | 4290 | 81.5 | 52.6 | A | F | A | A |
| Example 6 | | | | | | | | | | | | | |
| Comparative | F(5)-10 | 0.0 | 94 | 89 | F | F | | | | — | — | — | — |
| Example 7 | | | | | | | | | | | | | |
| Comparative | F(5)-5 | 0.0 | 97 | 91 | F | F | | | | — | — | — | — |
| Example 8 | | | | | | | | | | | | | |

The results shown in Table 2 reveal the following.

As is clear from the results shown in Examples 1 to 8, a thermosetting resin film having an infrared transmittance of less than 13% at 940 nm after a thermal curing treatment at 130° C. and 0.5 MPa for 240 minutes has excellent near-infrared shielding property and can prevent malfunction caused by near-infrared rays.

As is also clear from the results shown in Examples 1, 4, 7, 9, and 11, in a case where the thermosetting resin films of F (1)-45, F (2)-45, F (3)-45, F (7)-45, and F (8)-45 are used, the X value satisfies requirement (2) described above, and the evaluation results are good in the kerf recognition property, the designability, the film peeling, and the warpage.

In Comparative Example 6, the cured resin film was transparent, and thus the unevenness of the kerf was recognized. However, in Comparative Examples 6 to 8, it was found that when the cured resin film was formed from the curable resin film, the protective film was not formed in some regions at the end portion of the semiconductor chip, since, as compared with the cases of the Examples and the other Comparative Examples, a large decrease in viscosity was determined when the curable resin film was attached to the semiconductor wafer, and the grooves were filled with a large amount of the curable resin film.

### REFERENCE SIGNS LIST

10, 20 Composite sheet
30, 30′ Semiconductor chip-producing wafer
40, 40′ Semiconductor chip
1, 11, 11′ Release sheet
2, 12 Thermosetting resin film
3, 13 Substrate
4, 14 Release layer
15 Intermediate layer
21, 21′ Semiconductor wafer
21a, 21a′ Bump-formed surface
21b Back surface
22, 22′ Bump
23 Groove
X1 Thermosetting resin film
Y1 Release sheet
r1 Cured resin film
α1 First composite sheet
X2 Back surface curable resin film
Y2 Second release sheet
r2 Back surface cured resin film, back surface protective film
α2 Second composite sheet

1. A curable resin film for use in forming a cured resin film as a protective film on a bump-formed surface of a semiconductor chip having the bump-formed surface provided with a bump, the curable resin film satisfying requirement (1) below:
requirement (1): a near-infrared transmittance at 940 nm is less than 13% after thermal curing treatment at 130° C. and 0.5 MPa for 240 minutes.

2. The curable resin film according to claim 1, which comprises a black pigment.

3. The curable resin film according to claim 2, wherein a content of the black pigment is more than 0.5 mass % based on an entire amount of the curable resin film.

4. The curable resin film according to claim 1, which has a thickness of 1 μm or more.

5. The curable resin film according to claim 1, which is used for forming the cured resin film as the protective film on both the bump-formed surface and a side surface of the semiconductor chip.

6. A composite sheet comprising a laminated structure in which the curable resin film according to claim 1 and a release sheet are laminated.

7. The composite sheet according to claim 6, wherein the release sheet includes a substrate and a release layer, and the release layer faces the curable resin film.

8. The composite sheet according to claim 7, wherein the release sheet further includes an intermediate layer between the substrate and the release layer.

9. The composite sheet according to claim 7, wherein the release layer is a layer formed from a composition containing an ethylene-vinyl acetate copolymer.

10. A method for manufacturing a semiconductor chip, the method comprising steps (V1) to (V4) below in this order:
step (V1): preparing a semiconductor wafer having a bump-formed surface provided with a bump;
step (V2): attaching the curable resin film according to claim 1 by pressing to the bump-formed surface of the semiconductor wafer to cover the bump-formed surface of the semiconductor wafer with the curable resin film;
step (V3): curing the curable resin film to yield a semiconductor wafer having a cured resin film; and
step (V4): singulating the semiconductor wafer having the cured resin film into individual pieces to produce a semiconductor chip having the bump-formed surface covered with the cured resin film.

11. A method for manufacturing a semiconductor chip, the method comprising steps (S1), (S2), (S3), and (S4) below in this order:
step (S1): preparing a semiconductor chip-producing wafer in which grooves as predetermined singulation lines are formed in a bump-formed surface of a semiconductor wafer having the bump-formed surface provided with a bump, the grooves not reaching a back surface of the semiconductor wafer;
step (S2): attaching the curable resin film according to claim 5 by pressing to the bump-formed surface of the semiconductor chip-producing wafer to cover the bump-formed surface of the semiconductor chip-producing wafer with the curable resin film and to embed the curable resin film into the grooves formed in the semiconductor chip-producing wafer;
step (S3): curing the curable resin film to yield a semiconductor chip-producing wafer having a cured resin film; and
step (S4): singulating the semiconductor chip-producing wafer having the cured resin film along the predetermined singulation lines into individual pieces to produce a semiconductor chip in which at least the bump-formed surface and a side surface are covered with the cured resin film,
wherein the method further comprises step (S-BG) below after step (S2) and before step (S3), after step (S3) and before step (S4), or in step (S4):
step (S-BG): grinding the back surface of the semiconductor chip-producing wafer.

12. The method for manufacturing a semiconductor chip according to claim 10, which further comprises step (TA) below:
step (TA): forming a back surface protective film on the back surface of the semiconductor wafer.

13. The method for manufacturing a semiconductor chip according to claim 11, which further comprises step (TB) below:
step (TB): forming a back surface protective film on the back surface of the semiconductor chip-producing wafer.

14. A semiconductor chip comprising a cured resin film formed by curing the curable resin film according to claim 1 on a bump-formed surface of the semiconductor chip having the bump-formed surface provided with a bump, the semiconductor chip being provided with a near-infrared shielding function.

15. A semiconductor chip comprising a cured resin film formed by curing the curable resin film according to claim 5 on both a bump-formed surface and a side surface of the semiconductor chip having the bump-formed surface provided with a bump, the semiconductor chip being provided with a near-infrared shielding function.

16. The semiconductor chip according to claim 14, which further comprises a back surface protective film on a back surface of the semiconductor chip.
